(19) United States
(12) Patent Application Publication
(10) Pub. No.: US 2011/0261240 A1
(43) Pub. Date: Oct. 27, 2011

(54) SOLID-STATE IMAGING DEVICE

(75) Inventors: Takuya NOHARA, Osaka (JP); Sei SUZUKI, Osaka (JP)

(73) Assignee: PANASONIC CORPORATION, Osaka (JP)

(21) Appl. No.: 13/175,197

(22) Filed: Jul. 1, 2011

Related U.S. Application Data
(63) Continuation of application No. PCT/JP2009/007090, filed on Dec. 22, 2009.

(30) Foreign Application Priority Data
Jan. 7, 2009 (JP) 2009-002077

(51) Int. Cl. H04N 5/335; H01L 27/146

(52) U.S. Cl. 348/300; 250/208.1; 348/E05.091

(57) ABSTRACT

A solid-imaging device including an output unit of the FDA type and capable of generating accurate image signals and consuming less power is provided which includes: photoelectric conversion elements; a vertical CCD unit vertically transferring signal charges converted by the photoelectric conversion elements; a front-stage horizontal CCD unit horizontally transferring the signal charges, according to 4-phase drive signals having a 50% duty cycle; a rear-stage horizontal CCD unit disposed between the front-stage horizontal CCD unit and the output unit and horizontally transferring, according to 2-phase drive signals, the signal charges horizontally transferred from the front-stage horizontal CCD unit; a horizontal driver circuit generating the 4-phase drive signals; and a vertical/horizontal driver circuit generating the 2-phase drive signals, wherein the voltage amplitude of the 4-phase drive signals is smaller than the voltage amplitude of the 2-phase drive signals.

### CROSS REFERENCE TO RELATED APPLICATION

This is a continuation application of PCT application No. PCT/JP2009/007090 filed on Dec. 22, 2009, designating the United States of America.

### BACKGROUND OF THE INVENTION

(1) Field of the Invention

The present invention relates to a solid-state imaging device including a charge detecting unit of a floating diffusion amplifier (FDA) type.

(2) Description of the Related Art

Conventionally, a solid-state imaging device including a charge detecting unit of a floating diffusion amplifier (FDA) type has been known (see Patent Reference 1: Japanese Unexamined Patent Application Publication No. 5-095008).

FIG. 18 illustrates a schematic diagram of a conventional solid-state imaging device including a charge detecting unit of the FDA type. As shown in FIG. 18, a solid-state imaging device 700 includes a solid-state imaging element 701, a vertical driver circuit 702, a horizontal driver circuit 703, and an output amplifier 704. The solid-state imaging element 701 includes: a photoelectric conversion element unit made up of a plurality of photoelectric conversion elements 705 arranged in a grid pattern; a plurality of columns of vertical charge coupled device (CCD) units 706 arranged along respective columns of the photoelectric conversion elements 705; a horizontal CCD unit 707 disposed on the output terminal side of the respective vertical CCD units 706; and an output unit 708 disposed on the output terminal side of the horizontal CCD unit 707. The output unit 708 is a charge detecting unit of the FDA type.

Now, the solid-state imaging device 700 is described. The photoelectric conversion elements 705 convert received light into signal charges. These signal charges have charge quantity according to intensity of the light. The vertical CCD units 706 have electrode units of a 4-phase driving structure, for example. Specifically, each of the vertical CCD units 706 has four transfer electrodes for two photoelectric conversion elements 705. With this, 4-phase drive signals φV1, φV2, φV3, and φV4, which the vertical driver circuit 702 generates are applied to the four respective transfer electrodes. When 4-phase driven by the drive signals φV1 to φV4, the vertical CCD units 706 sequentially transfer, in the vertical direction on a per column basis, signal charges generated by the photoelectric conversion elements 705. The drive signals φV1 to φV4 which the vertical driver circuit 702 generates are pulse signals.

At the end of the respective vertical CCD units 706, the horizontal CCD unit 707 is disposed. Specifically, a front-stage horizontal CCD unit 707a includes four transfer electrodes for one vertical CCD unit 706. Of these four transfer electrodes, two adjacent transfer electrodes form one set, and to the two respective sets of the transfer electrodes, 2-phase drive signals φH1 and φH2 which the horizontal driver circuit 703 generates are applied. A terminal electrode unit 707b includes two transfer electrodes, and to the two transfer electrodes, a terminal electrode drive signal φHL which the horizontal driver circuit 703 generates is applied. The horizontal CCD unit 707 2-phase drives the front-stage horizontal CCD unit 707a by the drive signals φH1 and φH2, and drives the terminal electrode unit 707b by the drive signal φHL, thereby sequentially transferring, in the horizontal direction, the signal charges transferred from the output terminal of the vertical CCD unit 706. The drive signals φH1, φH2, and φHL, which the horizontal driver circuit 703 generates, and a reset signal φR for driving a reset gate 711 of the output unit 708 are pulse signals.

On the output side of the horizontal CCD unit 707, the output unit 708, which is a charge detecting unit of the FDA type, is provided. The output unit 708 includes an output gate 709, a floating diffusion (FD) 710 connected to the output amplifier 704, the reset gate 711, and a reset drain (RD) 712.

The output unit 708 sequentially detects signal charges horizontally transferred, and sequentially converts the detected signal charges into voltages. The output gate 709 has OG signals applied thereto at a given voltage, and when the drive signal φHL which is applied to the terminal electrode unit 707b of the horizontal CCD unit 707 is at “L” level such that the potential below the terminal electrode unit 707b is lower than the potential below the output gate 709 (OG barrier: potential barrier), the signal charges accumulated in the terminal electrode unit 707b are transferred to the FD 710.

Meanwhile, the reset drain 712 has a given voltage RD applied thereto. In addition, the reset signal φR which the horizontal driver circuit 703 generates is applied to the reset gate 711. When the reset gate 711 is placed in an ON state with the reset signal φR at “H” level, the signal charges accumulated in the FD 710 are reset, with the result that the voltage of the FD 710 becomes equal to the voltage RD of the reset drain 712. After that, when the reset signal φR changes to “L” level, the voltage of the FD 710 becomes a reference voltage (feedthrough level). Subsequently, when the signal charges are transferred from the horizontal CCD unit 707 to the FD 710, the voltage of the FD 710 becomes a voltage (signal level) which is lower than the reference voltage for those signal charges. As above, the FD 710 converts, into voltages, the signal charges transferred from the horizontal CCD unit 707. The output amplifier 704 amplifies the voltage signals converted by the output unit 708, to generate output signals Vₒᵤₜ. An external circuit (not shown) performs integrated correlated double sampling on the output signals Vₒᵤₜ to generate image signals which are then transmitted to a display (not shown). The integrated correlated double sampling is a process of generating image signals for a single pixel by calculating a difference between an integral quantity of the output signals Vₒᵤₜ at the feedthrough level and an integral quantity of the output signals Vₒᵤₜ at the signal level.

Next, a horizontal transfer operation and a charge detecting operation in the solid-state imaging device 700 are described. FIG. 19 is a timing chart illustrating behavior of the reset signal φR, the terminal electrode drive signal φHL, the 2-phase drive signals φH1 and φH2, and the output signal Vₒᵤₜ in the conventional solid-state imaging device. As shown in FIG. 19, the 2-phase drive signals φH1 and φH2 are the same in amplitude and opposite in phase, and the 2-phase drive signal φH1 and the terminal electrode drive signal φHL are the same in amplitude and in phase. The reset signal φR rises at substantially the same time as the terminal electrode drive signal φHL rises.

FIG. 20 shows a cross-sectional diagram and a potential distribution of the horizontal CCD unit and the output unit in the conventional solid-state imaging device. As shown in FIG. 20, in the front-stage horizontal CCD unit 707a of the horizontal CCD unit 707, an impurity implant region N⁻ where acceptor impurities are implanted is formed below the input-side transfer electrode of each pair of the two transfer electrodes. Likewise, an impurity implant region N⁻ where acceptor impurities are implanted is formed below the input-side transfer electrode of the two transfer electrodes forming the terminal electrode unit 707b to which the terminal electrode drive signal φHL is applied.

With the above structure, a potential well in which the signal charges are accumulated is formed below the transfer electrode right below which the above impurity implant region N⁻ is not formed, and the signal charges are prevented from flowing back to the area below the input-side transfer electrode.

The horizontal transfer operation and charge detecting operation in the solid-state imaging device 700 are described in detail below with reference to FIGS. 19 and 20. In FIG. 20, “H” level of the signal voltage indicates a positive potential, and its potential distribution shown in FIG. 20 is directed downward. Furthermore, “L” level of the signal voltage indicates a zero potential or a negative potential, and its potential distribution shown in FIG. 20 is directed upward.

First, at time t1, the drive signals φH1 and φHL change to “H” level while the drive signal φH2 changes to “L” level. As a result, the signal charges are accumulated in the potential well below the transfer electrode to which the drive signal φH1 is applied, and the signal charges transferred through the front-stage horizontal CCD unit 707a are accumulated in the potential well below the transfer electrode to which the drive signal φHL is applied. Furthermore, when the reset signal φR changes to “H” level, the signal charges accumulated in the FD 710 are reset, with the result that the voltage of the FD 710 becomes equal to the voltage RD of the reset drain 712.

Next, at time t2, the reset signal φR changes to “L” level. This sets the FD 710 at the reference voltage (feedthrough level), which means that the preparation for accumulating the signal charges in the FD 710 is completed.

Next, at times t3 and t4, the drive signals φH1 and φHL change to “L” level while the drive signal φH2 changes to “H” level. As a result, the signal charges accumulated below the first-phase transfer electrode move toward the potential well below the second-phase transfer electrode to which the drive signal φH2 is applied. Furthermore, the signal charges accumulated below the transfer electrode of the terminal electrode unit 707b move to the FD 710, with the result that the voltage of the FD 710 becomes a voltage (signal level) which is lower than the reference voltage according to the signal charges which have moved to the FD 710.

After this, the behavior from time t1 to t4 is repeated so that the signal charges of the respective columns of the vertical CCD units 706 which have been vertically transferred are horizontally transferred, and the horizontally transferred signal charges are voltage-converted to generate the output signals Vₒᵤₜ.

As above, in the solid-state imaging device including the charge detecting unit of the FDA type, the signal charges generated by the photoelectric conversion elements 705 are vertically transferred and horizontally transferred, and the output unit voltage-converts the signal charges.

However, in recent years, there is a high demand for solid-state imaging devices with reduced power consumption. As a measure to reduce the power consumption, it is effective to decrease the voltage of the drive signals. Especially, by decreasing the voltage of the drive signals for driving the horizontal CCD unit that is required to operate at high speed, it becomes possible to significantly reduce the power consumption. However, in the above-described conventional solid-state imaging device 700, a mere reduction in the voltage level of the drive signals which are generated by the horizontal driver circuit 703 causes a problem of a decrease in the dynamic range of the images or a failure to obtain accurate image signals due to causes such as a decrease in the saturated amount of signal charges which can be accumulated in the FD 710, or blooming.

For example, in the solid-state imaging device 700, when the voltage of the reset signal φR decreases, the signal charges accumulated in the FD 710 are completely reset and thus gone. This causes a decrease in the saturated amount of signal charges which can be accumulated in the FD 710.

Furthermore, in the solid-state imaging device 700, when the voltage of the drive signal φHL decreases, the potential below the terminal electrode unit 707b with the drive signal φHL at “H” level becomes lower. This causes the signal charges which have been transferred to the terminal electrode unit 707b, to undesirably move to the FD 710 over the OG barrier while the drive signal φHL is at “H” level, which is what is called “blooming”. In addition, blooming causes a decrease in the reference voltage of the FD 710, thereby reducing the saturated amount of signal charges. This results in a reduction in the dynamic range of the images to be displayed on the screen.

In order to solve the problem related to the transfer of signal charges, which is accompanied by a reduction in the voltage as described above, it is conceivable to increase the number of phases of the drive signals for driving the horizontal CCD unit and provide a driver which drives the horizontal CCD unit, separately from a driver which generates the terminal electrode drive signal and the reset signal.

FIG. 21 is a schematic diagram of a conventional solid-state imaging device including a charge detecting unit of the FDA type. As shown in FIG. 21, a solid-state imaging device 800 includes the solid-state imaging element 701, a vertical/horizontal driver circuit 802, a horizontal driver circuit 803, and the output amplifier 704. The solid-state imaging element 701 includes: the photoelectric conversion unit made up of the plurality of photoelectric conversion elements 705 arranged in a grid pattern; the plurality of vertical CCD units 706 arranged along the respective columns of the photoelectric conversion elements 705; a horizontal CCD unit 807 disposed on the output terminal side of the respective vertical CCD units 706; and the output unit 708 disposed on the output terminal side of the horizontal CCD unit 807. The solid-state imaging device 800 shown in FIG. 21 is different from the solid-state imaging device 700 shown in FIG. 18 in structures of the horizontal CCD unit 807, the vertical/horizontal driver circuit 802, and the horizontal driver circuit 803. The following describes only different configurations from the solid-state imaging device 700 by omitting explanations for the same configurations.

The vertical/horizontal driver circuit 802 generates, for example, 4-phase drive signals φV1, φV2, φV3, and φV4 for driving the respective vertical CCD units 706. Furthermore, the vertical/horizontal driver circuit 802 generates the terminal electrode drive signal φHL for driving the terminal electrode unit 807b of the horizontal CCD unit 807. In addition, the vertical/horizontal driver circuit 802 generates the reset signal φR for driving the reset gate 711 of the output unit 708. To the vertical/horizontal driver circuit 802, a power supply provides a voltage of 3.3 V, for example.

The horizontal driver circuit 803 generates 4-phase drive signals φH₄1, φH₄2, φH₄3, and φH₄4 for driving the front-stage horizontal CCD unit 807a of the horizontal CCD unit 807. To the horizontal driver circuit 803, a power supply provides a voltage of 1.8 V, for example. Thus, the horizontal driver circuit 803 generates the drive signals having a voltage level less than the drive signals which are generated by the vertical/horizontal driver circuit 802.

At the end of the respective vertical CCD units 706, the horizontal CCD unit 807 is disposed. Specifically, a front-stage horizontal CCD unit 807a includes eight transfer electrodes for two vertical CCD units 706.

Of these eight transfer electrodes, two adjacent transfer electrodes form one set, and to the four respective sets of the transfer electrodes, 4-phase drive signals φH₄1 to φH₄4 which the horizontal driver circuit 803 generates are applied.

A terminal electrode unit 807b includes two transfer electrodes, and to the two transfer electrodes, the terminal electrode drive signal φHL which the vertical/horizontal driver circuit 802 generates is applied.

With the above structure, the front-stage horizontal CCD unit 807a is 4-phase driven by the drive signals φH₄1 to φH₄4, and transfers, in the horizontal direction, the signal charges transferred from each of the output terminals of the vertical CCD units 706. Furthermore, the terminal electrode unit 807b is driven by the terminal electrode drive signal φHL, and horizontally transfers, to the output unit 708, the signal charges transferred from the front-stage horizontal CCD unit 807a.

Next, a horizontal transfer operation and a charge detecting operation in the solid-state imaging device 800 are described. FIG. 22 is a timing chart illustrating behavior of the reset signal φR, the 4-phase drive signals φ₄1 to φH₄4, the terminal electrode drive signal φHL, and the output signal Vₒᵤₜ in the conventional solid-state imaging device. FIG. 23 illustrates an example of a cross-sectional diagram and potential distribution of the horizontal CCD unit and the output unit in the conventional solid-state imaging device.

As shown in FIG. 22, the 4-phase drive signals φH₄1 to φH₄4 have the same amplitude (of 1.8 V, for example), and the reset signal φR and the terminal electrode drive signal φHL have the same amplitude (of 3.3 V, for example). Thus, the voltage level of the 4-phase drive signals φH₄1 to φH₄4 is less than the voltage level of the reset signal φR and the terminal electrode drive signal φHL. Furthermore, for the 4-phase drive signals φH₄1 to φH₄4, a ratio (a duty ratio) of a period for which the voltage level is at “H” to a period for which the voltage level is at “L” is 5:3.

As shown in FIG. 23, an impurity implant region N⁻ where acceptor impurities are implanted is formed below the input-side transfer electrode of the two transfer electrodes forming the terminal electrode unit 807b to which the terminal electrode drive signal φHL is applied. On the other hand, the impurity implant region N⁻ is not formed below the respective transfer electrodes of the front-stage horizontal CCD unit 807a to which the 4-phase drive signals φH₄1 to TH₄4 are applied.

For example, at time t0 shown in FIG. 22, the above-described duty ratio of the 4-phase drive signals φH₄1 to φH₄4 is 5:3 below the transfer electrodes of the front-stage horizontal CCD unit 807a shown in FIG. 23, with the result that the 3-phase drive signals φH₄2 to φH₄4 applied to six adjacent transfer electrodes can have a voltage level of “H” and that a potential well is formed across and below the six transfer electrodes. This makes it possible to secure a capacity to accumulate one signal charge even when the voltage level of the 4-phase drive signals of the front-stage horizontal CCD unit 807a is low. Thus, the power consumption of the solid-state imaging device 800 can be reduced by decreasing the voltage of the drive signals of the front-stage horizontal CCD unit in the solid-state imaging device 800.

### SUMMARY OF THE INVENTION

However, as the above-described solid-state imaging device 800, when the front-stage horizontal CCD unit 807a is driven using the 4-phase drive signals φH₄1 to φH₄4 with a duty ratio of 5:3, the output signal Vₒᵤₜ involves coupling noise which is attributed to rising and falling pulses of each of the drive signals φH₄1 to φH₄4 (indicated by broken lines in FIG. 22). FIG. 24 illustrates waveforms of output for explaining the noise which is generated in the output signals in the conventional solid-state imaging device. As shown in FIG. 24, especially when the above coupling noise is generated during the reference voltage integration period and the signal voltage integration period, accurate output signals cannot be obtained, which degrades image quality.

In view of the above problem, an object of the present invention is to provide a solid-state imaging device which is capable of generating accurate image signals and consumes less power.

In order to achieve the above object, a solid-state imaging device according to an aspect of the present invention is a solid-state imaging device including a charge detecting unit of a floating diffusion amplifier type, the solid-state imaging device including: a plurality of photoelectric conversion elements which convert received light into signal charges; a plurality of vertical transfer units configured to vertically transfer the signal charges converted by the photoelectric conversion elements; a first horizontal transfer unit configured to horizontally transfer, according to N-phase drive signals, where N is an integer equal to or greater than 3, the signal charges vertically transferred from the vertical transfer units; a second horizontal transfer unit spaced apart from the photoelectric conversion elements and the vertical transfer units and disposed between the first horizontal transfer unit and the charge detecting unit, and configured to horizontally transfer the signal charges which have been horizontally transferred from the first horizontal transfer unit, to the charge detecting unit according to L-phase drive signals, where L is an integer equal to or greater than 2 and satisfies L≦N; a first driver unit configured to generate the N-phase drive signals for driving the first horizontal transfer unit; and a second driver unit configured to generate the L-phase drive signals for driving the second horizontal transfer unit, wherein the L-phase drive signals include a signal having a larger voltage amplitude than a voltage amplitude of each of the N-phase drive signals.

According to this aspect, the first horizontal transfer unit which horizontally transfers the signal charges vertically transferred from the vertical transfer unit is N-phase driven, where N is an integer equal to or greater than 3, with the result that the number of transfer electrodes of the first horizontal transfer unit increases as compared to the case where both the first horizontal transfer unit and the second horizontal transfer unit which is connected to the charge detecting unit are L-phase driven, where L≦N. This increase in the number of the transfer electrodes makes it possible to secure a saturated amount of signal charges to be accumulated in the transfer channel even when the voltage amplitude of the drive signals for driving the first horizontal transfer unit is set to be smaller.

Furthermore, the increase in the number of phases for driving the first horizontal transfer unit is accompanied by an increase in the number of rising and falling edges of pulse waveforms of the drive signals. In the structure according an aspect of the present invention, the second horizontal transfer unit which is L-phase driven, where L is an integer equal to or greater than 2, is disposed between the first horizontal transfer unit and the charge detecting unit. As compared to the first horizontal transfer unit, the second horizontal transfer unit has a smaller total number of electrodes and therefore has a smaller capacitance. By disposing this second horizontal transfer unit, it is possible to prevent the generation of the coupling noise in the output voltage, which results from coupling, in the charge detecting unit, of noise attributed to rising and falling of the above pulse signals through the transfer channel.

The above structure thus makes it possible to generate accurate image signals with less noise and to reduce the power consumption.

Furthermore, it may be possible that the voltage amplitudes in respective phases of the L-phase drive signals are all V_{L}, and the voltage amplitudes in respective phases of the N-phase drive signals are all V_{N}, where V_{L} is greater than V_{N}.

According to this aspect, the first horizontal transfer unit is driven at a low voltage, which allows for a reduction in power consumption.

Furthermore, it may be possible that the first horizontal transfer unit includes a plurality of first horizontal transfer electrodes to which the N-phase drive signals are applied, and a first horizontal transfer channel formed below the first horizontal transfer electrodes, in a part of the first horizontal transfer channel, a first n-type implant region which creates a potential step inside the first horizontal transfer channel is formed for each of the first horizontal transfer electrodes, the second horizontal transfer unit includes a plurality of second horizontal transfer electrodes to which the L-phase drive signals are applied, and a second horizontal transfer channel formed below the second horizontal transfer electrodes, in a part of the second horizontal transfer channel, a second n-type implant region which creates a potential step inside the second horizontal transfer channel is formed for each of the second horizontal transfer electrodes, and the first n-type implant region has a different impurity concentration from an impurity concentration of the second n-type implant region.

According to this aspect, the potential level inside the transfer channel of the first horizontal transfer unit can be subdivided, which makes it possible to form an incline of potential for facilitating the transfer of signal charges from the input side to the output side of the first transfer unit. Thus, it becomes possible to accelerate the horizontal transfer of signal charges.

Furthermore, it may be possible that the second horizontal transfer unit includes a plurality of second horizontal transfer electrodes to which the L-phase drive signals are applied, and a second horizontal transfer channel formed below the second horizontal transfer electrodes, the integer L is a multiple of 2, and the voltage amplitudes of the L-phase drive signals for driving two adjacent ones of the second horizontal transfer electrodes are different from each other.

According to this aspect, it becomes possible to form the incline of potential for transferring signal charges between adjacent transfer electrodes, without implanting acceptor impurities in the transfer channel of the second horizontal transfer unit. Thus, the step of implanting impurities is omitted, which allows for simplification of the manufacturing process. In addition, the power consumption can be reduced because the voltage applied to the transfer channel in which no acceptor impurities are implanted is lower than the voltage applied to the transfer channel in which the acceptor impurities are to be implanted.

Furthermore, it may be possible that a third driver unit configured to generate a reset signal for resetting the signal charges accumulated in the charge detecting unit is provided, and among the voltage amplitudes of the L-phase drive signals, one is the same as a voltage amplitude of the reset signal and an other is the same as the voltage amplitude of one of the N-phase drive signals.

Furthermore, it may be possible that the voltage amplitude in each phase of the N-phase drive signals is V_{N}, and the voltage amplitude in each phase of the L-phase drive signals is V_{L} or V_{N}, where V_{L} is greater than V_{N}.

According to this aspect, the voltage supply for the drive signals having lower voltage for driving the first horizontal transfer unit can be used as a part of the voltage supply for the drive signals for driving the second horizontal transfer unit. It therefore becomes possible to reduce the power consumption.

Furthermore, it may be possible that a part of the N-phase drive signals is common with a part of the L-phase drive signals.

According to this aspect, the circuitry of the first driver unit which generates the drive signals for driving the first horizontal transfer unit and the circuitry of the second driver unit which generates the drive signals for driving the second horizontal transfer unit can be partly shared. Thus, the power consumption can be further reduced.

Furthermore, it may be possible that the first driver unit and the second driver unit respectively generate the N-phase drive signals having a 50% duty cycle and the L-phase drive signals having a 50% duty cycle.

Furthermore, it may be possible that rising timing and falling timing in a phase of the N-phase drive signals are the same, respectively, as falling timing and rising timing in an other phase of the N-phase drive signals.

According to this aspect, it becomes possible to cancel the noise which is generated by rising and falling of the drive signals for driving the first horizontal transfer unit. Likewise, it becomes possible to cancel the noise which is generated by rising and falling of the drive signals for driving the second horizontal transfer unit. Thus, the coupling noise which results from coupling of the above noise in the charge detecting unit can be prevented from occurring in the output voltage.

Furthermore, it may be possible that the first horizontal transfer unit includes the first horizontal transfer electrodes to which the N-phase drive signals out of phase by 180 degrees are applied and which are of equal length and width.

According to this aspect, the waveform quality of the pulse drive signals which are opposite in phase can be met. This improves the effect of canceling the noise which is generated by rising and falling of the pulse drive signals.

Furthermore, it may be possible that the solid-state imaging device includes a plurality of lines connected to the first horizontal transfer electrodes and through which the N-phase drive signals are supplied to the first horizontal transfer electrodes, and among the lines, lines through which signal voltages out of phase by 180 degrees are concurrently supplied are adjacent to each other.

According to this aspect, in a wiring unit for supplying the drive signals from the respective driver units to the corresponding horizontal transfer units, the pulse drive signals which are opposite in phase are close to each other, which improves the effect of cancelling the noise which is generated by rising and falling of the pulse drive signals.

Furthermore, it may be possible that rising timing and falling timing of one of the N-phase drive signals which is applied to one of horizontal transfer electrodes which is located at a last stage of the first horizontal transfer unit are the same, respectively, as falling timing and rising timing of one of the L-phase drive signals which is applied to one of second horizontal transfer electrodes which is located at a first stage of the second horizontal transfer unit.

According to this aspect, it becomes possible to reduce the coupling noise which is generated between the first horizontal transfer unit and the second horizontal transfer unit.

Furthermore, it may be possible that the second horizontal transfer unit includes a plurality of second horizontal transfer electrodes to which the L-phase drive signals are applied, and a second horizontal transfer channel formed below the second horizontal transfer electrodes, and the second horizontal transfer channel includes a plurality of second horizontal transfer channel regions which correspond to the second horizontal transfer electrodes and whose lengths in a transfer direction or widths in an orthogonal direction to the transfer direction are different from each other.

It is desired that the charge detecting unit required to accurately voltage-convert the signal charges have a smaller capacitance in order to avoid an output voltage waveform distortion. On the other hand, the first horizontal transfer unit is required to have enough capacitance to secure the dynamic range of the output signals and to transfer the signal charges completely. Accordingly, the charge detecting unit and the first horizontal transfer unit are different in the optimum shape of each of the transfer channel regions corresponding to the transfer electrodes in which the signal charges are accumulated. With this structure, it is possible to provide a consistent horizontal transfer by changing the width and length of each of the transfer channel regions of the second horizontal transfer unit.

Furthermore, it may be possible that the first horizontal transfer unit includes a plurality of first horizontal transfer electrodes to which the N-phase drive signals are applied, and a first horizontal transfer channel formed below the first horizontal transfer electrodes, and the first horizontal transfer channel includes a plurality of first horizontal transfer channel regions which correspond to the first horizontal transfer electrodes and whose lengths in a transfer direction or widths in an orthogonal direction to the transfer direction are different from each other.

In the first horizontal transfer unit, the capacitance of the transfer channel is desirably optimized according to the required saturated amount of signal charges. With this structure, it becomes possible to optimize the shape of each of the transfer channel regions corresponding to the respective transfer electrodes of the first horizontal transfer unit, and thereby possible to contribute to downsizing of the solid-state imaging device.

Furthermore, the solid-state imaging device according to an aspect of the present invention is a solid-state imaging device including a charge detecting unit of a floating diffusion amplifier type, the solid-state imaging device including: a plurality of photoelectric conversion elements which convert received light into signal charges; a plurality of vertical transfer units configured to vertically transfer the signal charges converted by the photoelectric conversion elements; a first horizontal transfer unit configured to horizontally transfer, according to N-phase drive signals, where N is an integer equal to or greater than 3, the signal charges vertically transferred from the vertical transfer units; a second horizontal transfer unit including a second horizontal transfer electrode for horizontally transferring, to the charge detecting unit, the signal charges horizontally transferred from the first horizontal transfer unit, and a second horizontal transfer channel formed below the second horizontal transfer electrode; a first driver unit configured to generate the N-phase drive signals for driving the first horizontal transfer unit; and a second driver unit configured to generate a second horizontal transfer drive signal for driving the second horizontal transfer unit, wherein a voltage amplitude of each of the N-phase drive signals is smaller than a voltage amplitude of each of the second horizontal transfer drive signals, the N-phase drive signals have a 50% duty cycle, and the second horizontal transfer drive signals have a 50% duty cycle, and in a part of the second horizontal transfer channel, a second n-type implant region which creates a potential step inside the second horizontal transfer channel is formed for each of the second horizontal transfer electrodes.

The increase in the number of phases for driving the first horizontal transfer unit is accompanied by an increase in the number of rising and falling edges of pulse waveforms of the drive signals. In the structure according an aspect of the present invention, the horizontal transfer drive signals are driven at a 50% duty cycle, so that the noise which is generated by rising and falling of the drive signals for driving the first horizontal transfer unit can be canceled. Thus, the coupling noise which results from coupling of the above noise in the charge detecting unit can be prevented from occurring in the output voltage. Furthermore, the transfer channel of the second horizontal transfer electrodes is implanted with a higher concentration of acceptor impurities than the first horizontal transfer unit, so that the signal charges can be prevented from flowing back to the first horizontal transfer unit and thus horizontally transferred smoothly.

Furthermore, the present invention can not only provide a solid-state imaging device having the above features, but also provide a camera including such a solid-state imaging device with a structure and an effect which are the same as described above.

In the solid-state imaging device according to an aspect of the present invention, the voltage of the horizontal transfer drive signals is decreased, and the coupling noise which is attributed to rising and falling timing of pulses of the drive signals is reduced, which make it possible to generate accurate image signals and reduce the power consumption.

### FURTHER INFORMATION ABOUT TECHNICAL BACKGROUND TO THIS APPLICATION

The disclosure of Japanese Patent Application No. 2009-002077 filed on Jan. 7, 2009 including specification, drawings and claims is incorporated herein by reference in its entirety.

The disclosure of PCT application No. PCT/JP2009/007090 filed on Dec. 22, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 illustrates a schematic diagram of a solid-state imaging device according to the first embodiment of the present invention;

FIG. 2 illustrates a cross-sectional diagram and potential distribution of a horizontal CCD unit and an output unit of the solid-state imaging device according to the first embodiment of the present invention;

FIG. 3 is a timing chart illustrating behavior of a reset signal φR, 4-phase drive signals, 2-phase drive signals, and an output signal Vₒᵤₜ in the solid-state imaging device according to the first embodiment of the present invention;

FIG. 4 is a timing chart illustrating behavior of a reset signal φR, 4-phase drive signals, 2-phase drive signals, and an output signal Vₒᵤₜ in a solid-state imaging device according to the first variation of the first embodiment of the present invention;

FIG. 5 illustrates a cross-sectional diagram and potential distribution of a horizontal CCD unit and an output unit of a solid-state imaging device according to the second variation of the first embodiment of the present invention;

FIG. 6 illustrates a schematic diagram of a horizontal CCD unit, an output unit, a vertical/horizontal driver circuit, and a horizontal driver circuit of a solid-state imaging device according to the third variation of the first embodiment of the present invention;

FIG. 7 illustrates a schematic diagram of a horizontal CCD unit, an output unit, a vertical/horizontal driver circuit, and a horizontal driver circuit of a solid-state imaging device according to the fourth variation of the first embodiment of the present invention;

FIG. 8 illustrates a layout of a horizontal CCD unit and signal lines of a solid-state imaging device according to the fifth variation of the first embodiment of the present invention;

FIG. 9 illustrates a schematic diagram of a solid-state imaging device according to the second embodiment of the present invention;

FIG. 10 illustrates a cross-sectional diagram and potential distribution of a horizontal CCD unit of a solid-state imaging device according to the second embodiment of the present invention;

FIG. 11 is a timing chart illustrating behavior of a reset signal φR, 4-phase drive signals, pseudo 2-phase drive signals, and an output signal Vₒᵤₜ in the solid-state imaging device according to the second embodiment of the present invention;

FIG. 12 is a timing chart illustrating behavior of a reset signal φR, 4-phase drive signals, pseudo 2-phase drive signals, and an output signal Vₒᵤₜ in a solid-state imaging device according to the first variation of the second embodiment of the present invention;

FIG. 13 illustrates a schematic diagram of a solid-state imaging device according to the third embodiment of the present invention;

FIG. 14 illustrates a cross-sectional diagram and potential distribution of a horizontal CCD unit of the solid-state imaging device according to the third embodiment of the present invention; FIG. 15 is a timing chart illustrating behavior of a reset signal φR, 4-phase drive signals, pseudo 2-phase drive signals, and an output signal Vₒᵤₜ in the solid-state imaging device according to the third embodiment of the present invention;

FIG. 16 illustrates a cross-sectional diagram and potential distribution of a horizontal CCD unit and a terminal electrode unit of a solid-state imaging device according to an implementation of the present invention;

FIG. 17A illustrates a function diagram of a camera incorporating a solid-state imaging device according to an implementation of the present invention;

FIG. 17B illustrates an exterior view of a digital still camera incorporating a solid-state imaging device according to an implementation of the present invention;

FIG. 17C illustrates an exterior view of a video camera incorporating a solid-state imaging device according to an implementation of the present invention;

FIG. 18 illustrates a schematic diagram of a conventional solid-state imaging device including a charge detecting unit of the FDA type;

FIG. 19 is a timing chart illustrating behavior of a reset signal φR, a terminal electrode drive signal φHL, 2-phase drive signals φH1 and φH2, and an output signal Vₒᵤₜ in the conventional solid-state imaging device;

FIG. 20 illustrates a cross-sectional diagram and potential distribution of the horizontal CCD unit and the output unit in the conventional solid-state imaging device;

FIG. 21 illustrates a schematic diagram of a conventional solid-state imaging device including a charge detecting unit of the FDA type.

FIG. 22 is a timing chart illustrating behavior of a reset signal φR, 4-phase drive signals φH₄1 to φH₄4, a terminal electrode drive signal φHL, and an output signal Vₒᵤₜ in the conventional solid-state imaging device;

FIG. 23 illustrates an example of a cross-sectional diagram and potential distribution of a horizontal CCD unit and an output unit in the conventional solid-state imaging device; and

FIG. 24 illustrates waveforms of output for explaining noise which is generated in the output signals in the conventional solid-state imaging device.

### DESCRIPTION OF THE PREFERRED EMBODIMENT(S)

### First Embodiment

A solid-state imaging device according to the present embodiment includes: a charge detecting unit of a floating diffusion amplifier (FDA) type; a photoelectric conversion element which converts received light into signal charges; a vertical transfer unit configured to vertically transfer the signal charges; a first horizontal transfer unit configured to horizontally transfer the signal charges according to, for example, 4-phase drive signals; and a second horizontal transfer unit spaced apart from the photoelectric conversion element and the vertical transfer unit and disposed between the first horizontal transfer unit and the charge detecting unit, and configured to horizontally transfer the signal charges to the charge detecting unit according to, for example, 2-phase drive signals, the signal charges having been horizontally transferred from the first horizontal transfer unit, wherein a voltage amplitude in each phase of the 4-phse drive signals is smaller than a voltage amplitude of the 2-phase drive signals. As compared to the case of 2-phase driving the first horizontal transfer unit, the above structure increases the number of transfer electrodes of the first horizontal transfer unit in which the signal charges can be accumulated, so that the saturated amount of signal charges to be accumulated in the transfer channel can be secured even when the voltage amplitude of the drive signals for driving the first horizontal transfer unit is set to be smaller. Furthermore, the increase in the number of phases for driving the first horizontal transfer unit is accompanied by an increase in the number of rising and falling edges of pulse waveforms of the drive signals. In response to this, the second horizontal transfer unit which is 2-phase driven is disposed between the first horizontal transfer unit and the charge detecting unit. The second horizontal transfer unit has a small total number of electrodes and therefore has a small capacitance. By disposing this second horizontal transfer unit, it is possible to prevent the generation of the coupling noise in the output voltage, which results from coupling, in the charge detecting unit, of noise attributed to rising and falling of the above pulse signals through the transfer electrodes, the signal lines, and the like.

The following describes the solid-state imaging device according to embodiments of the present invention with reference to the drawings.

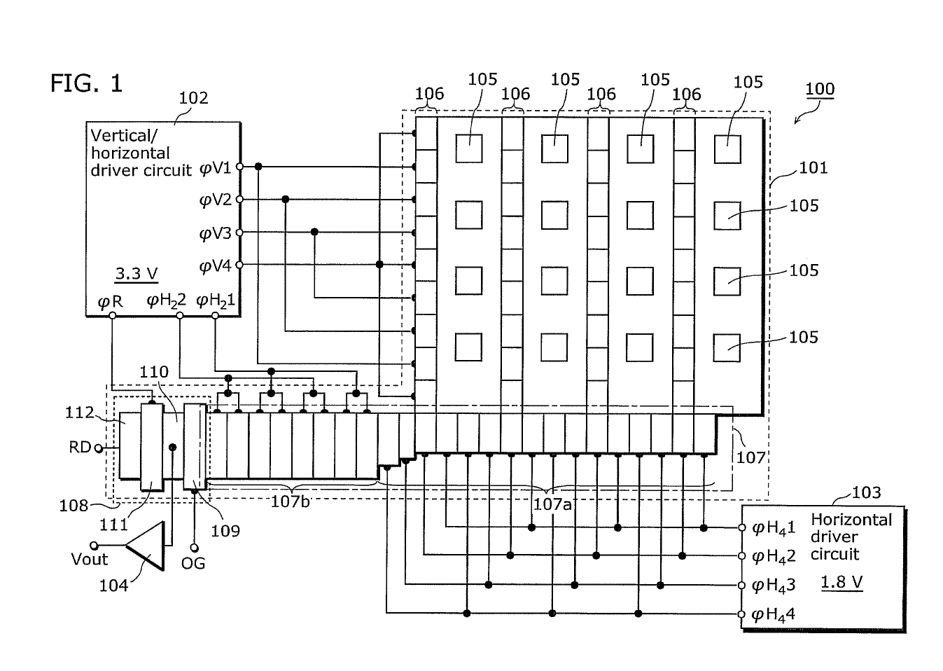

FIG. 1 illustrates a schematic diagram of a solid-state imaging device according to the first embodiment of the present invention. As shown in FIG. 1, a solid-state imaging device 100 includes a solid-state imaging element 101, a vertical/horizontal driver circuit 102, a horizontal driver circuit 103, and an output amplifier 104. The solid-state imaging device 101 includes: a photoelectric conversion element unit made up of a plurality of photoelectric conversion elements 105 arranged in a grid pattern; a plurality of columns of vertical charge coupled device (CCD) units 106 arranged along respective columns of the photoelectric conversion elements 105; a horizontal CCD unit 107 disposed on the output terminal side of the respective vertical CCD units 106; and an output unit 108 disposed on the output terminal side of the horizontal CCD unit 107. The output unit 108 is a charge detecting unit of the FDA type.

The vertical/horizontal driver circuit 102 generates 4-phase drive signals φV1, φV2, φV3, and φV4 for driving the respective vertical CCD units 106. Moreover, the vertical/horizontal driver circuit 102 serves as the second driver unit which generates 2-phase drive signals φH₂1 and φH₂2 for driving a rear-stage horizontal CCD unit 107b of the horizontal CCD unit 107. Furthermore, the vertical/horizontal driver circuit 102 serves as the third driver unit which generates the reset signal φR for driving a reset gate 111 of the output unit 108. To the vertical/horizontal driver circuit 102, a power supply provides a voltage of 3.3 V, for example.

The horizontal driver circuit 103 serves as the first driver unit which generates 4-phase drive signals φH₄1, φH₄2, φH₄3, and φH₄4 for driving the front-stage horizontal CCD unit 107a of the horizontal CCD unit 107. To the horizontal driver circuit 103, a power supply provides a voltage of 1.8 V, for example. Thus, the horizontal driver circuit 103 generates the drive signals having a voltage level less than the drive signals which are generated by the vertical/horizontal driver circuit 102.

It is to be noted that a voltage of the power which is supplied to the vertical/horizontal driver circuit 102 and the horizontal driver circuit 103 is not limited to the above-stated voltage. The vertical/horizontal driver circuit 102 is a driver IC which is capable of handling a voltage having a larger amplitude than a voltage which the horizontal driver circuit 103 can handle.

In addition, the driver circuit which drives the vertical CCD unit 106 and the driver circuit which drives the horizontal CCD unit 107 may be mutually independent circuits. Alternatively, the vertical/horizontal driver circuit 102 and the horizontal driver circuit 103 may be combined into a one-chip driver IC.

The photoelectric conversion elements 105 convert received light into signal charges. These signal charges have charge quantity according to intensity of the light.

The vertical CCD units 106 constitute a vertical transfer unit and have electrode units of a 4-phase driving structure. Specifically, each of the vertical CCD units 106 has four transfer electrodes for two photoelectric conversion elements 105. With this, 4-phase drive signals φV1, φV2, φV3, and φV4, which the vertical/horizontal driver circuit 102 generates are applied to the four respective transfer electrodes. When 4-phase driven by the drive signals φV1 to φV4, the vertical CCD units 106 sequentially transfer, in the vertical direction on a per column basis, signal charges generated by the photoelectric conversion elements 105. The drive signals φV1 to φV4 which the vertical/horizontal driver circuit 102 generates are pulse signals. The configuration may be such that the signal charges are vertically transferred by vertical CCD units which employ a driving system other than the 4-phase driving system (e.g., 3-phase driving system).

The horizontal CCD unit 107 includes the front-stage horizontal CCD unit 107a and the rear-stage horizontal CCD unit 107b. At the output terminals of the respective vertical CCD units 106, the front-stage horizontal CCD unit 107a is disposed.

The front-stage horizontal CCD unit 107a serves as the first horizontal transfer unit and includes, for example, four transfer electrodes for one column of the vertical CCD units 106. To these four respective transfer electrodes, 4-phase drive signals φH₄1 to φH₄4 which the horizontal driver circuit 103 generates are applied. When 4-phase driven by the drive signals φH₄1 to φH₄4, the front-stage horizontal CCD unit 107a transfers, in the horizontal direction, signal charges transferred from the output terminals of the respective vertical CCD units 106. The drive signals φH₄1 to φH₄4 which the horizontal driver circuit 103 generates are pulse signals.

The rear-stage horizontal CCD unit 107b serves as the second horizontal transfer unit and is spaced apart from the above photoelectric conversion element unit and the vertical CCD units 106 and disposed between the front-stage horizontal CCD unit 107a and the output unit 108. Furthermore, the rear-stage horizontal CCD unit 107b includes plural sets (four sets in FIG. 1) of a pair of two adjacent transfer electrodes, and to the respective sets, the 2-phase drive signals φH₂1 and φH₂2 which the vertical/horizontal driver circuit 102 generates are applied alternately. When driven by the drive signals φH₂1 and φH₂2, the rear-stage horizontal CCD unit 107b horizontally transfers, to the output unit 108, signal charges transferred from the front-stage horizontal CCD unit 107a. The drive signals φH₂1 and φH₂2 which the vertical/horizontal driver circuit 102 generates are pulse signals.

The output unit 108 is a charge detecting unit of the FDA type and disposed on the output side of the rear-stage horizontal CCD unit 107b. The output unit 108 includes an output gate 109, a floating diffusion (FD) 110 connected to the output amplifier 104, the reset gate 111, and a reset drain 112.

The output unit 108 sequentially detects signal charges horizontally transferred, and sequentially converts the detected signal charges into voltages. The output gate 109 has OG signals applied thereto at a given voltage. When the drive signal φH₂2 which is applied to the transfer electrode located in the last stage of the rear-stage electrode unit 707b is at “L” level such that the potential below the transfer electrode is lower than the potential below the output gate 109 (OG barrier: potential barrier), the signal charges accumulated in the transfer electrode are transferred to the FD 110.

Meanwhile, the reset drain 112 has a given voltage RD applied thereto. In addition, the reset signal φR which the vertical/horizontal driver circuit 102 generates is applied to the reset gate 111. When the reset gate 111 is placed in an ON state with the reset signal φR at “H” level, the signal charges accumulated in the FD 110 are reset, with the result that the voltage of the FD 110 becomes equal to the voltage RD of the reset drain 112. After that, when the reset signal φR changes to “L” level, the voltage of the FD 110 becomes a reference voltage (feedthrough level). Subsequently, when the signal charges are transferred from the rear-stage horizontal CCD unit 107b to the FD 110, the voltage of the FD 110 becomes a voltage (signal level) which is lower than the reference voltage for those signal charges. As above, the FD 110 converts, into voltages, the signal charges transferred from the rear-stage horizontal CCD unit 107b. The reset signal φR for driving the reset gate 111 of the output unit 108 is a pulse signal.

The output amplifier 104 amplifies the voltage signals converted by the output unit 108, to generate output signals Vₒᵤₜ. An external circuit (not shown) performs integrated correlated double sampling on the output signals Vₒᵤₜ to generate image signals which are then transmitted to a display (not shown). The integrated correlated double sampling is a process of generating image signals for a single pixel by calculating a difference between an integral quantity of the output signals Vₒᵤₜ at the feedthrough level and an integral quantity of the output signals Vₒᵤₜ at the signal level.

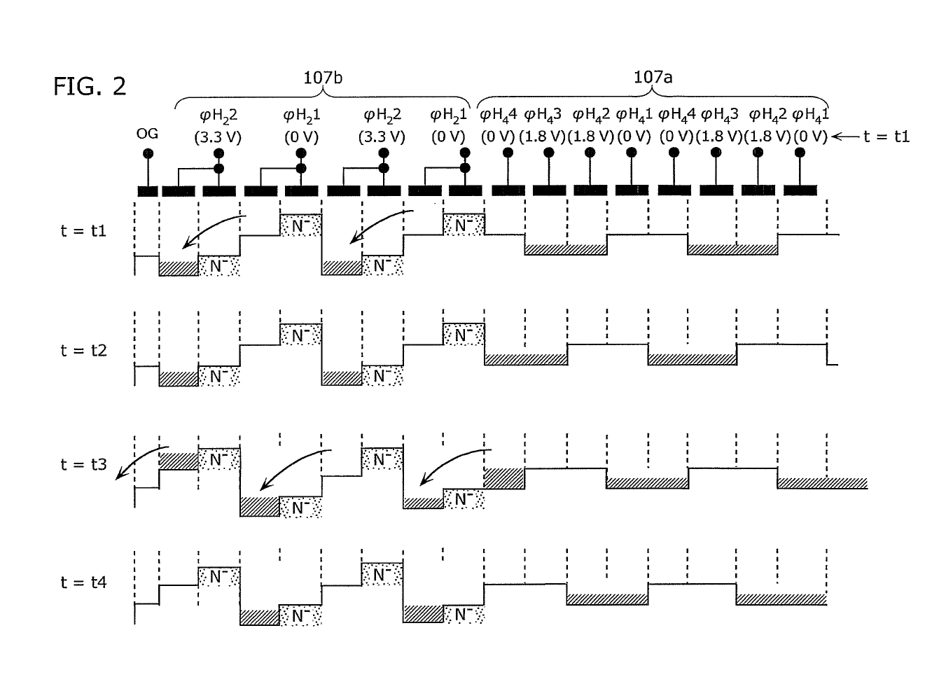

FIG. 2 illustrates a cross-sectional diagram and potential distribution of the horizontal CCD unit and the output unit of the solid-state imaging device according to the first embodiment of the present invention. As shown in FIG. 2, the 4-phase drive signals φH₄1 to φH₄4 are applied to the four respective adjacent transfer electrodes in the front-stage horizontal CCD unit 107a. The signal charges which are horizontally transferred are accumulated in the potential well formed across the two adjacent transfer electrodes. This allows a smooth horizontal transfer in the front-stage horizontal CCD unit 107a even when the 4-phase drive signals φH₄1 to φH₄4 are set at “H” level (1.8 V) which is lower than “H” level (3.3 V) of the 2-phase drive signals φH₂1 and φH₂2 in the rear-stage horizontal CCD unit 107b.

Furthermore, in the rear-stage horizontal CCD unit 107b, an impurity implant region N⁻ where acceptor impurities are implanted is formed below the input-side transfer electrode of each pair of the two transfer electrodes.

With the above structure, the potential well is formed below the transfer electrode right below which the above impurity implant region N⁻ is not formed, and the signal charges are accumulated in this well. In addition, the signal charges are prevented from flowing back to the area below the input-side transfer electrode.

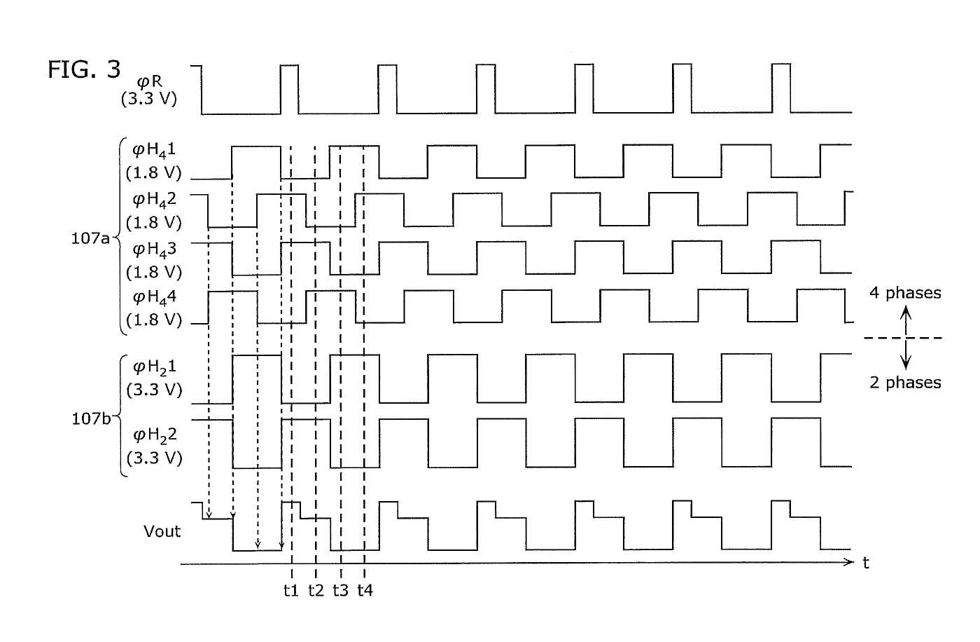

Next, a horizontal transfer operation and a charge detecting operation in the solid-state imaging device 100 are described. FIG. 3 is a timing chart illustrating behavior of the reset signal φR, the 4-phase drive signals, the 2-phase drive signals, and the output signal Vₒᵤₜ in the solid-state imaging device according to the first embodiment of the present invention. As shown in FIG. 3, the voltage amplitudes in the respective phases of the 4-phase drive signals φH₄1 to φH₄4 are all 1.8 V. Furthermore, the 4-phase drive signals are driven at a 50% duty cycle, and each phase is delayed by 90 degrees with respect to a corresponding phase of the drive signal in the previous stage. As to the 2-phase drive signals φH₂1 and φH₂2, the voltage amplitudes in both phases are all 3.3 V. Furthermore, the 2-phase drive signals are driven at a 50% duty cycle, and both phases of the 2-phase drive signals are opposite to each other. The reset signal φR rises at substantially the same time as the drive signal φH₂2 rises.

The horizontal transfer operation and charge detecting operation in the solid-state imaging device 100 are described in detail below with reference to FIGS. 2 and 3. In FIG. 2, “H” level of the signal voltage indicates a positive potential, and its potential distribution shown in FIG. 2 is directed downward. Furthermore, “L” level of the signal voltage indicates a zero potential or a negative potential, and its potential distribution shown in FIG. 2 is directed upward. On the other hand, in the pulse waveforms shown in FIG. 3, “H” level of the signal voltage indicates the upward direction while “L” level of the signal voltage indicates the downward direction.

First, at time t1, the drive signals φH₄2 and φH₄3 change to “H” level while the drive signals φH₄1 and φH₄4 change to “L” level. As a result, the signal charges transferred through the front-stage horizontal CCD unit 107a are accumulated in the potential well below the transfer electrodes to which the drive signals φH₄2 to φH₄3 are applied. At the same time, the drive signal φH₂2 changes to “H” level, and the drive signal φH₂1 changes to “L” level. As a result, the signal charges accumulated in the transfer channel region corresponding to the transfer electrode to which the drive signal φH₂1 is applied are transferred to another transfer channel region which is located on the output side of the above transfer channel region and to which the drive signal φH₂2 is applied. Furthermore, the reset signal φR (not shown) changes to “H” level, the signal charges accumulated in the FD 110 are reset, with the result that the voltage of the FD 110 becomes equal to the voltage RD of the reset drain 112.

Next, at time t2, the drive signals φH₄3 and φH₄4 change to “H” level. As a result, the signal charges transferred through the front-stage horizontal CCD unit 107a are accumulated in the potential well below the transfer electrodes to which the drive signals φH₄3 and φH₄4 are applied. Furthermore, the reset signal φR changes to “L” level. This sets the FD 110 at the reference voltage (feedthrough level), which means that the preparation for accumulating the signal charges in the FD 110 is completed.

Next, at time t3, the drive signals φH₄4 and φH₄1 change to “H” level while the drive signal φH₄3 and φH₄2 change to “L” level. As a result, the signal charges transferred through the front-stage horizontal CCD unit 107a are accumulated in the potential well below the transfer electrodes to which the drive signals φH₄4 and φH₄1 are applied. At the same time, the drive signal φH₂1 changes to “H” level, and the drive signal φH₂2 changes to “L” level. As a result, the signal charges accumulated in the transfer channel region to which the drive signal φH₂2 is applied are transferred to another transfer channel region which is located on the output side of the above transfer channel region and to which the drive signal φH₂1 is applied. Furthermore, the signal charges accumulated in the transfer channel region located in the last stage of the front-stage horizontal CCD unit 107a are transferred to one of the transfer channel regions located in the first stage of the rear-stage horizontal CCD unit 107b, in which the impurity implant region N⁻ is not formed. In addition, the signal charges accumulated in the transfer channel region located in the last stage of the rear-stage horizontal CCD unit 107b move to the FD 110, with the result that the voltage of the FD 110 becomes a voltage (signal level) which is lower than the reference voltage according to the signal charges which have moved to the FD 110.

Next, at time t4, the drive signals φH₄2 and φH₄1 change to “H” level. As a result, the signal charges transferred through the front-stage horizontal CCD unit 107a are accumulated in the potential well below the transfer electrodes to which the drive signals φH₄2 and φH₄1 are applied.

After this, the behavior from time t1 to t4 is repeated so that the signal charges of the respective columns of the vertical CCD units 106 which have been vertically transferred are horizontally transferred, and the horizontally transferred signal charges are voltage-converted to generate the output signals Vₒᵤₜ.

As above, in the solid-state imaging device 100 including the charge detecting unit of the FDA type, the signal charges generated by the photoelectric conversion elements 105 are vertically transferred and horizontally transferred, and the output unit 108 voltage-converts the signal charges.

The above structure and operation secure a capacity to accumulate signal charges even when the voltage amplitude of signals for 4-phase driving the front-stage horizontal CCD unit 107a is set to be smaller than the voltage amplitude of signals for driving the vertical CCD units 106 and the rear-stage horizontal CCD unit 107b.

In addition, since the 4-phase drive signals of the front-stage horizontal CCD unit 107a and the 2-phase drive signals of the rear-stage horizontal CCD unit 107b have a duty ratio of 50%, it becomes possible to cancel the noise which is generated by rising and falling of the 4-phase drive signals and the 2-phase drive signals.

Furthermore, in the structure according to the present embodiment, the rear-stage horizontal CCD unit 107b that has a small capacitance and is driven by the 2-phase drive signals with the small number of rising and falling edges is disposed between the output unit 108 and the front-stage horizontal CCD unit 107a that is driven by the 4-phase drive signals with the large number of rising and falling edges. This makes it possible to prevent the generation of the coupling noise in the output voltage, which results from coupling, in the output unit 108, of noise generated in the front-stage horizontal CCD unit 107a.

Thus, the voltage of the horizontal transfer drive signals is decreased, and the coupling noise which is attributed to rising and falling timing of pulses of the drive signals is reduced, which make it possible to generate accurate image signals and reduce the power consumption.

While the front-stage horizontal CCD unit 107a includes four transfer electrodes for one column of the vertical CCD units 106 in the above structure, the transfer electrodes are not limited to such arrangement. For example, when the solid-state imaging device is provided with a control unit capable of selectively controlling the transfer of signal charges from the vertical CCD unit to the horizontal CCD unit, the signal charges for one horizontal line can be divided into several portions and thus output. This means that it is sufficient that the four transfer electrodes are provided for the predetermined number of columns of the vertical CCD units by which number the signal charges are divided, and as an example, in the case where the signal charges for one horizontal line are divided by two and thus output, the four transfer electrodes are provided for two columns of the vertical CCD units. In this case, the length of the transfer electrodes can be longer, which can reduce the width thereof extending in a direction orthogonal to the transfer direction of the transfer channel region, and moreover, the decrease in the number of electrodes can reduce the capacitance between the electrodes, which can lead to a further reduction in the power consumption.

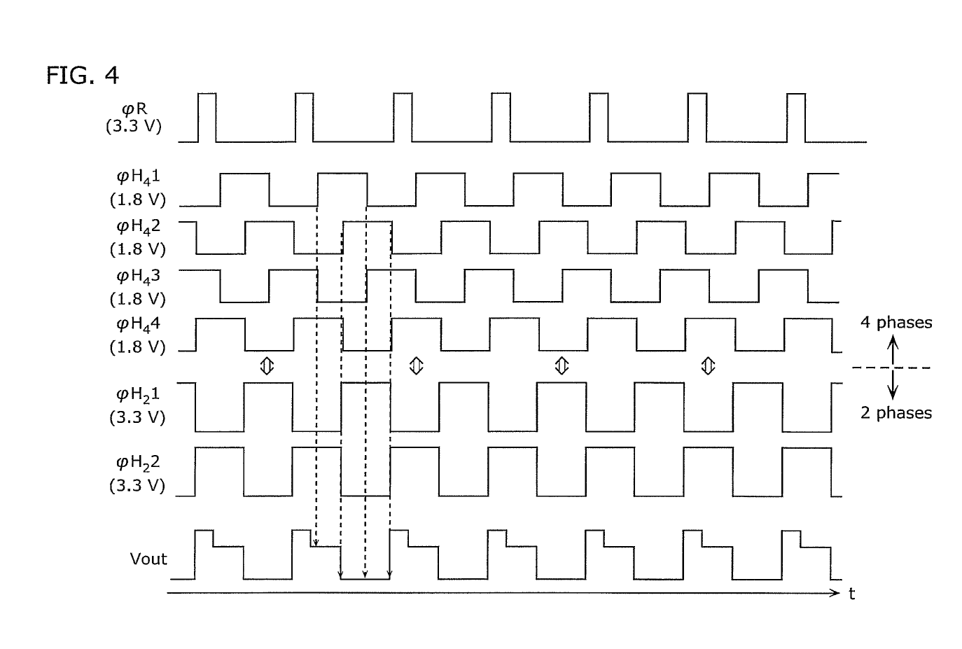

FIG. 4 is a timing chart illustrating behavior of a reset signal φR, 4-phase drive signals, 2-phase drive signals, and an output signal Vₒᵤₜ in a solid-state imaging device according to the first variation of the first embodiment of the present invention. The behavior timing chart shown in FIG. 4 is different from the behavior timing chart of the solid-state imaging device 100 according to the first embodiment shown in FIG. 3 only in the driving phases of the drive signals φH₄1 to φH₄4 for 4-phase driving the front-stage horizontal CCD unit 107a. The following describes only different points from the first embodiment by omitting explanations for the same points. The voltage amplitudes of the respective phases of the 4-phase drive signals φH₄1 to φH₄4 are all 1.8 V. Furthermore, the 4-phase drive signals are driven at a 50% duty cycle, and each phase is delayed by 90 degrees with respect to a corresponding phase of the drive signal in the previous stage. The timing of the drive signal φH₂1 which is applied to the transfer electrode located in the first stage of the rear-stage horizontal CCD unit 107b and the timing of the drive signal φH₄4 which is applied to the transfer electrode located in the last stage of the front-stage horizontal CCD unit 107a are adjusted so that these drive signals are out of phase by 180 degrees.

By so doing, the noise which is generated in the front-stage horizontal CCD unit 107a and the rear-stage horizontal CCD unit 107b is cancelled so that the coupling noise which is generated between the front-stage horizontal CCD unit 107a and the rear-stage horizontal CCD unit 107b can be reduced.

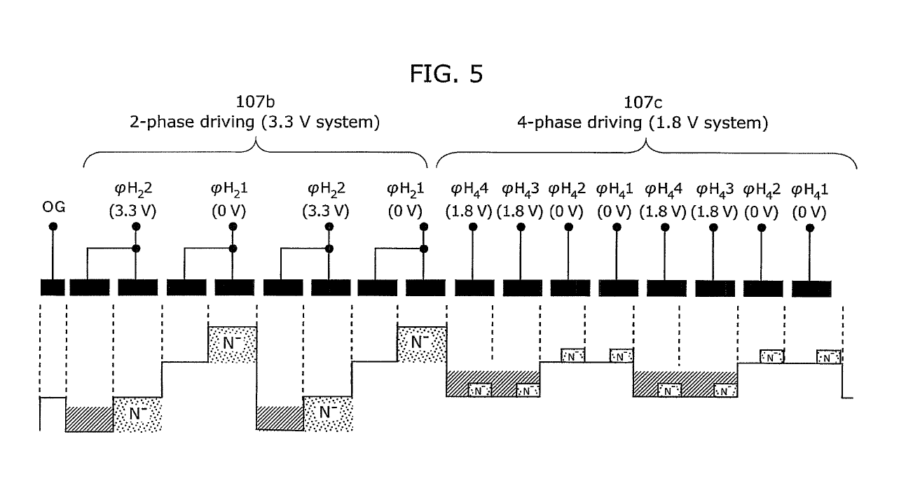

FIG. 5 illustrates a cross-sectional diagram and potential distribution of a horizontal CCD unit and an output unit of a solid-state imaging device according to the second variation of the first embodiment of the present invention. The horizontal CCD unit and the output unit of the solid-state imaging device shown in FIG. 5 are different from the horizontal CCD unit and the output unit of the solid-state imaging device 100 according to the first embodiment shown in FIG. 2 only in the structure of each of the transfer channel regions of a front-stage horizontal CCD unit 107c corresponding to the front-stage horizontal CCD unit 107a. The following describes only different points from the first embodiment by omitting explanations for the same points. The horizontal CCD unit of the solid-state imaging device according to the second variation of the first embodiment of the present invention includes the front-stage horizontal CCD unit 107c and the rear-stage horizontal CCD unit 107b. In each of the transfer channel regions of the front-stage horizontal CCD unit 107c, an impurity implant region N⁻ where acceptor impurities are implanted is formed in a part of the input-side region.

Since this structure allows each of the transfer channel regions of the front-stage horizontal CCD unit 107c to have more potential levels, it is possible to form an incline of potential for facilitating the transfer of signal charges from the input side to the output side within the transfer channel region. Thus, it becomes possible to accelerate the horizontal transfer of signal charges and thereby to reduce remains which have not been transferred.

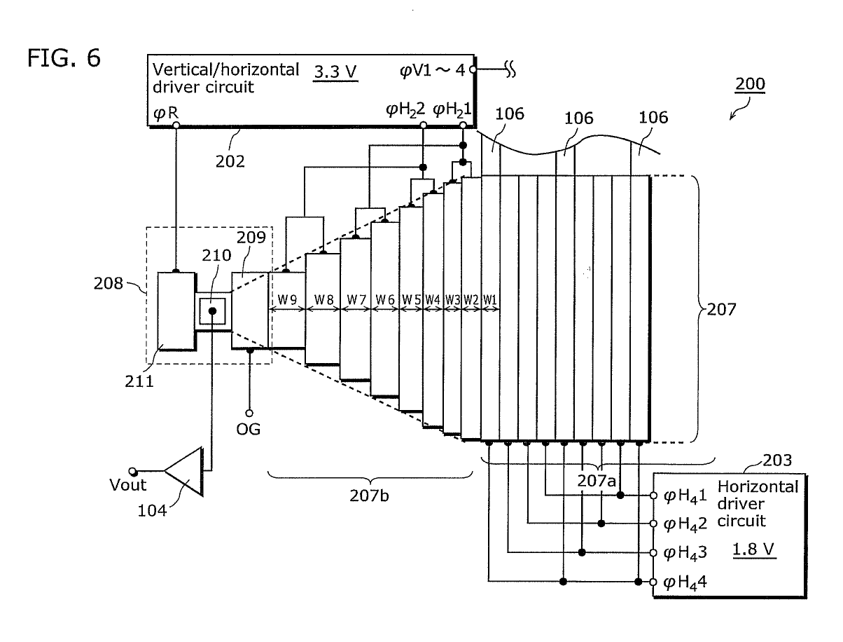

FIG. 6 illustrates a schematic diagram of a horizontal CCD unit, an output unit, a vertical/horizontal driver circuit, and a horizontal driver circuit of a solid-state imaging device according to the third variation of the first embodiment of the present invention. A solid-state imaging device 200 shown in FIG. 6 includes a vertical/horizontal driver circuit 202, a horizontal driver circuit 203, a horizontal CCD unit 207, and an output unit 208. The horizontal CCD unit 207 includes a front-stage horizontal CCD unit 207a and a rear-stage horizontal CCD unit 207b. The output unit 208 includes an output gate 209, an FD 210 connected to the output amplifier 104, and a reset gate 211. The solid-state imaging device 200 shown in FIG. 6 is different from the solid-state imaging device 100 according to the first embodiment shown in FIG. 1 only in the shape of each of the transfer channel regions of the rear-stage horizontal CCD unit 207b. The following describes only different points from the first embodiment by omitting explanations for the same points. The widths of the transfer channel regions of the rear-stage horizontal CCD unit 207b along the orthogonal direction to the transfer direction are smaller from the transfer channel region in the first stage to the transfer channel region in the last stage. It is desired that the output unit 208 required to voltage-convert the signal charges with high conversion efficiency make the capacitance of the FD 210 small. In the meantime, the front-stage horizontal CCD unit 207a is required to have enough saturation capacitance to secure the dynamic range of the output signals and to transfer the signal charges completely. Accordingly, the optimum shape of the channel in which the signal charges are accumulated is different between the output unit 208 and the front-stage horizontal CCD unit 207a. With this structure, it is possible to provide a consistent horizontal transfer by changing the width and length of each of the transfer channel regions of the rear-stage horizontal CCD unit 207b.

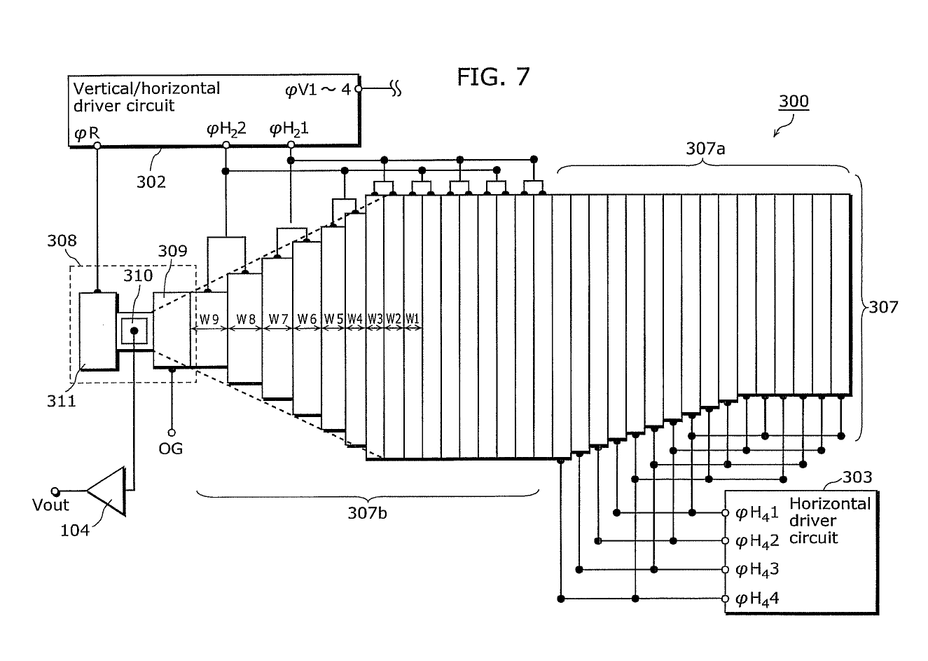

FIG. 7 illustrates a schematic diagram of a horizontal CCD unit, an output unit, a vertical/horizontal driver circuit, and a horizontal driver circuit of a solid-state imaging device according to the fourth variation of the first embodiment of the present invention. A solid-state imaging device 300 shown in FIG. 7 includes a vertical/horizontal driver circuit 302, a horizontal driver circuit 303, a horizontal CCD unit 307, and an output unit 308. The horizontal CCD unit 307 includes a front-stage horizontal CCD unit 307a and a rear-stage horizontal CCD unit 307b. The output unit 308 includes an output gate 309, an FD 310 connected to the output amplifier 104, and a reset gate 311. The solid-state imaging device 300 shown in FIG. 7 is different from the solid-state imaging device 100 according to the first embodiment shown in FIG. 1 only in the shape of each of the transfer channel regions of the front-stage horizontal CCD unit 307a and the rear-stage horizontal CCD unit 307b. The following describes only different points from the first embodiment by omitting explanations for the same points. The widths of the transfer channel regions of the rear-stage horizontal CCD unit 307b along the orthogonal direction to the transfer direction are smaller from the transfer channel region in the first stage to the transfer channel region in the last stage. Furthermore, the number of transfer electrodes and transfer channel regions of the rear-stage horizontal CCD unit 307b is larger than those in the rear-stage horizontal CCD unit 107b shown in FIG. 2. The effect obtained by changing the shape of the transfer channel region is the same as the effect described in the third variation of the first embodiment. In addition, the increase in the number of transfer electrodes and transfer channel regions in the rear-stage horizontal CCD unit 307b can lead to a further reduction in the above-mentioned coupling noise which occurs in the output voltage due to driving pulses of the front-stage horizontal CCD unit.

Furthermore, in the front-stage horizontal CCD unit 307a, the length, in the transfer direction, and the width, in the orthogonal direction to the transfer direction, of each of the transfer electrodes and the transfer channel regions are optimized according to the required saturated amount of signal charges. With this, it is possible to contribute to downsizing of the solid-state imaging device.

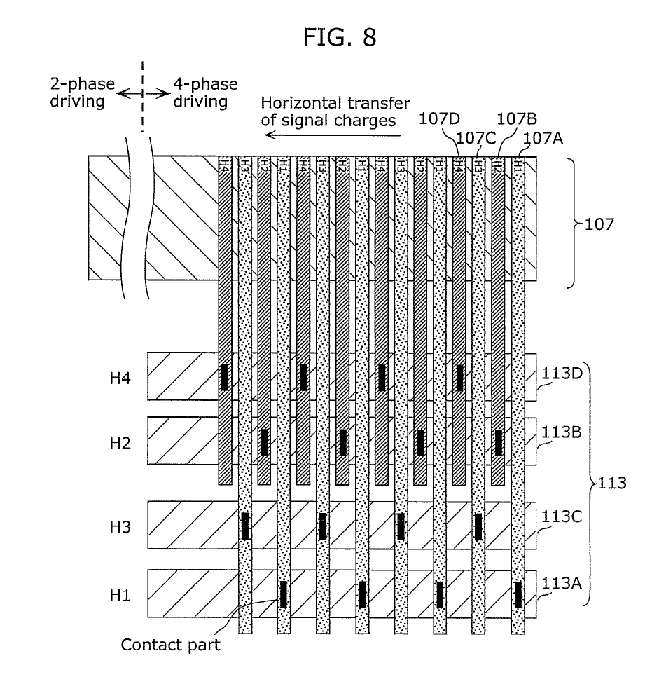

FIG. 8 illustrates a layout of a horizontal CCD unit and signal lines of a solid-state imaging device according to the fifth variation of the first embodiment of the present invention. The solid-state imaging device shown in FIG. 8 includes the horizontal CCD unit 107 and signal lines 113. The solid-state imaging device shown in FIG. 8 is different from the solid-state imaging device 100 shown in FIG. 1 only in the detailed layout of the transfer electrodes of the front-state horizontal CCD unit and in the arrangement of the signal lines for applying the drive signals to the transfer electrodes. The following describes only different points from the first embodiment by omitting explanations for the same points.

The front-stage horizontal CCD unit includes transfer electrodes 107A, 1076, 107C, and 107D to which 4-phase drive signals φH₄1, φH₄2, φH₄3, and φH₄4 are applied respectively. The transfer electrodes 107A to 107D are polysilicon gates, for example. The signal lines 113 electrically connect the horizontal driver circuit 103 to the transfer electrodes 107A to 107D. For example, the signal lines 113 are bus lines made of Al, and include four signal lines 113A, 113B, 113C, and 113D which are connected to the transfer electrodes 107A, 107B, 107C, and 107D, respectively.

The solid-state imaging device according to the fifth variation of the present embodiment is driven based on the behavior timing chart shown in FIG. 3, for example. The signal lines 113A and 113C through which the drive signals φH₄1 and φH₄3, 180 degrees out of phase with respect to each other, are applied to the transfer electrodes are disposed adjacent to each other. The signal lines 113B and 113D through which the drive signals φH₄2 and φH₄4, 180 degrees out of phase with respect to each other, are applied to the transfer electrodes are disposed adjacent to each other.

With this, the drive signals which are opposite in phase can be close to each other in the signal lines 113 for supplying the drive signals from the horizontal driver circuit 103 to the front-stage horizontal CCD unit 107a. Thus, the effect of canceling the noise which is generated by rising and falling of the pulse drive signals improves.

In addition, the transfer electrodes 107A and 107C in which the drive signals are opposite in phase are the same in length and width. The transfer electrodes 107B and 107D in which the drive signals are opposite in phase are the same in length and width.

With this, the waveform quality of the pulse drive signals which are opposite in phase can be met. Thus, the effect of canceling the noise which is generated by rising and falling of the pulse drive signals improves.

### Second Embodiment

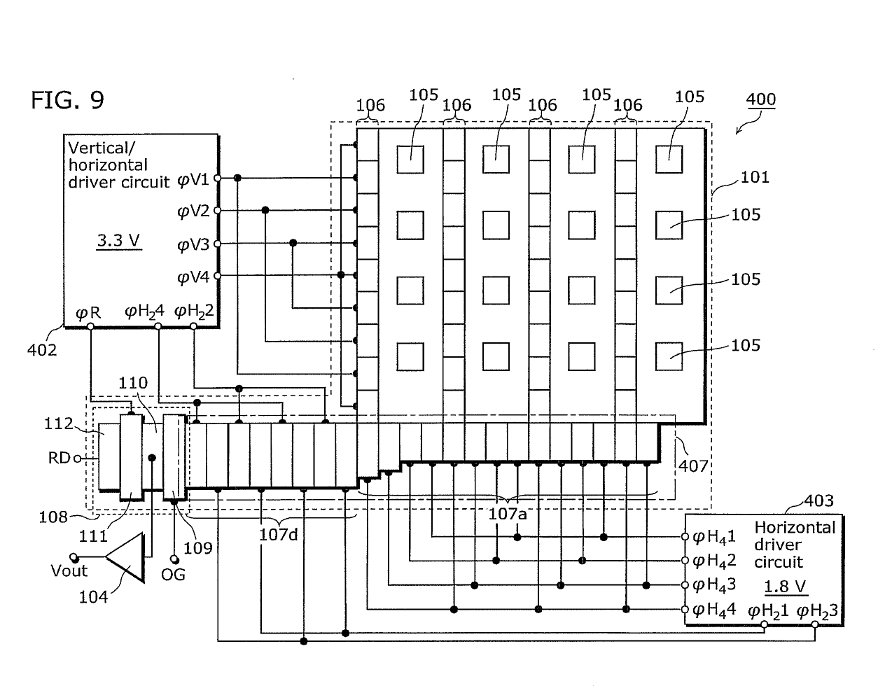

FIG. 9 illustrates a schematic diagram of a solid-state imaging device according to the second embodiment of the present invention. As shown in FIG. 9, a solid-state imaging device 400 includes the solid-state imaging element 101, a vertical/horizontal driver circuit 402, a horizontal driver circuit 403, and the output amplifier 104. The solid-state imaging element 101 includes: the photoelectric conversion unit made up of the plurality of photoelectric conversion elements 105 arranged in a grid pattern; the plurality of columns of vertical CCD units 106 arranged along the respective columns of the photoelectric conversion elements 105; a horizontal CCD unit 407 disposed on the output terminal side of the respective vertical CCD units 106; and the output unit 108 disposed on the output terminal side of the horizontal CCD unit 407. The solid-state imaging device 400 shown in FIG. 9 is different from the solid-state imaging device 100 according to the first embodiment shown in FIG. 1 in structures and operations of a rear-stage horizontal CCD unit 107d, the vertical/horizontal driver circuit 402, and the horizontal driver circuit 403. The following describes only different points from the first embodiment by omitting explanations for the same points.

The vertical/horizontal driver circuit 402 generates 4-phase drive signals φV1, φV2, φV3, and φV4 for driving the respective vertical CCD units 106. Moreover, the vertical/horizontal driver circuit 402 serves as the second driver unit which generates pseudo 2-phase drive signals φH₂2 and φH₂4 for driving a part of the rear-stage horizontal CCD unit 107d of the horizontal CCD unit 407. Furthermore, the vertical/horizontal driver circuit 402 serves as the third driver unit which generates the reset signal φR for driving the reset gate 111 of the output unit 108. To the vertical/horizontal driver circuit 402, a power supply provides a voltage of 3.3 V, for example.

The horizontal driver circuit 403 serves as the first driver unit which generates 4-phase drive signals φH₄1, φH₄2, φH₄3, and φH₄4 for driving the front-stage horizontal CCD unit 107a a of the horizontal CCD unit 407. Moreover, the vertical/horizontal driver circuit 403 serves also as the second driver unit which generates pseudo 2-phase drive signals φH₂1 and φH₂3 for driving a part of the rear-stage horizontal CCD unit 107d of the horizontal CCD unit 407. To the horizontal driver circuit 403, a power supply provides a voltage of 1.8 V, for example. Thus, the horizontal driver circuit 403 generates the drive signals having a voltage level less than the drive signals which are generated by the vertical/horizontal driver circuit 402.

It is to be noted that a voltage of the power which is supplied to the vertical/horizontal driver circuit 402 and the horizontal driver circuit 403 is not limited to the above-stated voltage.

The horizontal CCD unit 407 includes the front-stage horizontal CCD unit 107a and the rear-stage horizontal CCD unit 107d.

The rear-stage horizontal CCD unit 107d serves as the second horizontal transfer unit and is spaced apart from the above photoelectric conversion element unit and the vertical CCD units 106 and disposed between the front-stage horizontal CCD unit 107a and the output unit 108. The 4-phase drive signals φH₂1 to φH₂4 are applied to the four respective adjacent transfer electrodes in the rear-stage horizontal CCD unit 107d. It is to be noted that the drive signals φH₂1 and φH₂2 are in phase and have different voltage amplitudes of 1.8 V and 3.3 V, respectively. Likewise, the drive signals φH₂3 and φH₂4 are in phase and have different voltage amplitudes of 1.8 V and 3.3 V, respectively. That is, the drive signals for driving two adjacent transfer electrodes in the rear-stage horizontal CCD unit 107d have different voltage amplitudes.

In the present embodiment, the drive signals φH₂1 and φH₂3 are pulse signals which are generated by the horizontal driver circuit 403 and have a voltage amplitude of 1.8 V. The drive signals φH₂2 and φH₂4 are pulse signals which are generated by the vertical/horizontal driver circuit 402 and have a voltage amplitude of 3.3 V. This allows the voltage supply for the drive signals having lower voltage for driving the front-stage horizontal CCD unit 107a to be used as a part of the voltage supply for the drive signals for driving the rear-stage horizontal CCD unit 107d. It therefore becomes possible to reduce the power consumption.

In the present embodiment, the above-mentioned pseudo 2-phase driving indicates driving which involves: two phases being the same phase and having different voltage amplitudes; and two other phases being the same phase which is different from the phase of the above two phases, and having different voltage amplitudes. Furthermore, this pseudo 2-phase driving is defined as 4-phase driving by regarding the difference in voltage amplitude as different phases.

It is to be noted that the drive signals φH₂1 and φH₂3 of the above pseudo 2-phase driving may be generated not by the horizontal driver circuit 403 but by another driver circuit or the like.

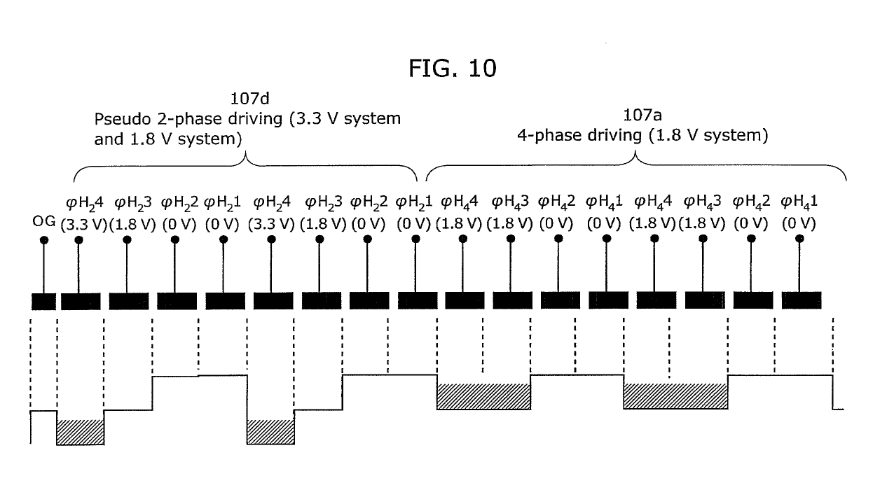

FIG. 10 illustrates a cross-sectional diagram and potential distribution of the horizontal CCD unit of the solid-state imaging device according to the second embodiment of the present invention. As shown in FIG. 10, the 4-phase drive signals φH₄1 to φH₄4 are applied to the four respective adjacent transfer electrodes in the front-stage horizontal CCD unit 107a. The signal charges which are horizontally transferred are accumulated in the potential well formed across the two adjacent transfer electrodes. This allows a smooth horizontal transfer in the front-stage horizontal CCD unit 107a even when the 4-phase drive signals φH₄1 to φH₄4 are set at “H” level (1.8 V) which is lower than “H” level (3.3 V) of the pseudo 2-phase drive signals φH₂2 and φH₂4 in the rear-stage horizontal CCD unit 107d.

Furthermore, in the rear-stage horizontal CCD unit 107d, the drive signals for driving the two adjacent transfer electrodes have different voltage amplitudes (1.8 V and 3.3 V) as described above.

With the above structure, it becomes possible to form the incline of potential for transferring signal charges between adjacent transfer channel regions, without implanting acceptor impurities in the transfer channel regions of the rear-stage horizontal CCD unit 107d. Thus, the step of implanting impurities is omitted, which allows for simplification of the manufacturing process. In addition, the power consumption can be reduced because the voltage applied to the transfer channel region in which no acceptor impurities are implanted is lower than the voltage applied to the transfer channel region in which the acceptor impurities are to be implanted.

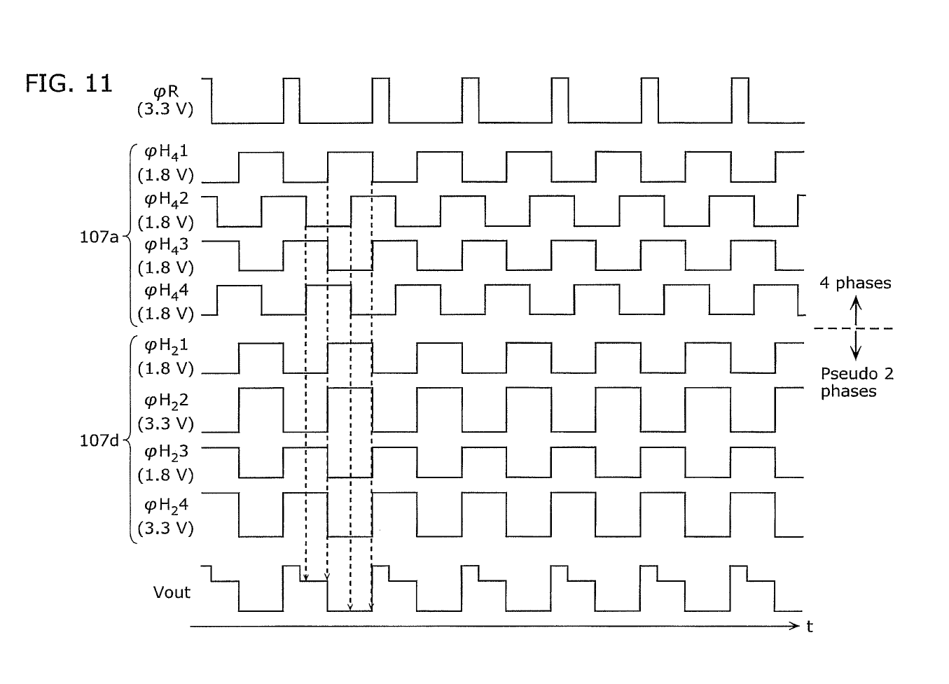

Next, a horizontal transfer operation in the solid-state imaging device 400 is described. FIG. 11 is a timing chart illustrating behavior of a reset signal φR, 4-phase drive signals, pseudo 2-phase drive signals, and an output signal Vₒᵤₜ in the solid-state imaging device according to the second embodiment of the present invention. The behavior timing chart of the solid-state imaging device 400 shown in FIG. 11 is different from the behavior timing chart of the solid-state imaging device 100 shown in FIG. 3 only in that the rear-stage horizontal CCD unit 107d is pseudo-2-phase driven. The following describes only different points from the behavior timing chart according to the first embodiment shown in FIG. 3, by omitting explanations for the same points.

The pseudo 2-phase drive signals φH₂1 and φH₂3 have a voltage amplitude of 1.8 V. On the other hand, the pseudo 2-phase drive signals φH₂2 and φH₂4 have a voltage amplitude of 3.3 V. Furthermore, all the pseudo 2-phase drive signals are driven at a 50% duty cycle, and the pseudo 2-phase drive signals φH₂1 and φH₂2 are in phase, and the pseudo 2-phase drive signals φH₂3 and φH₂4 are in phase. The reset signal φR rises at substantially the same time as the pseudo 2-phase drive signal φH₂4 rises.

In the horizontal transfer operation of the rear-stage horizontal CCD unit 107d, the behavior timing of the pseudo 2-phase drive signals φH₂1 and φH₂2 is the same as that of the 2-phase drive signal φH₂1 shown in FIG. 3, and the behavior timing of the pseudo 2-phase drive signals φH₂3 and φH₂4 is the same as that of the 2-phase drive signal φH₂2 shown in FIG. 3.

The above structure and operation secure a capacity to accumulate signal charges even when the voltage amplitude of signals for 4-phase driving the front-stage horizontal CCD unit 107a is set to be smaller than the voltage amplitudes of signals for driving the vertical CCD units 106 and a part of the rear-stage horizontal CCD unit 107d.

In addition, since the 4-phase drive signals of the front-stage horizontal CCD unit 107a and the pseudo 2-phase drive signals of the rear-stage horizontal CCD unit 107d have a duty ratio of 50%, it becomes possible to cancel the noise which is generated by rising and falling of the 4-phase drive signals and the pseudo 2-phase drive signals.

Furthermore, in the structure according to the present embodiment, the rear-stage horizontal CCD unit 107d that has a small capacitance and is driven by the pseudo 2-phase drive signals with the small number of rising and falling edges is disposed between the output unit 108 and the front-stage horizontal CCD unit 107a that is driven by the 4-phase drive signals with the large number of rising and falling edges. This makes it possible to prevent the generation of the coupling noise in the output voltage, which results from coupling, in the output unit 108, of noise generated in the front-stage horizontal CCD unit 107a.

Thus, the voltage of the horizontal transfer drive signals is decreased, and the coupling noise which is attributed to rising and falling timing of pulses of the drive signals is reduced, which make it possible to generate accurate image signals and reduce the power consumption.

This allows the voltage supply for the drive signals having lower voltage for driving the front-stage horizontal CCD unit 107a to be used as a part of the voltage supply for the drive signals for driving the rear-stage horizontal CCD unit 107d. It therefore becomes possible to further reduce the power consumption.

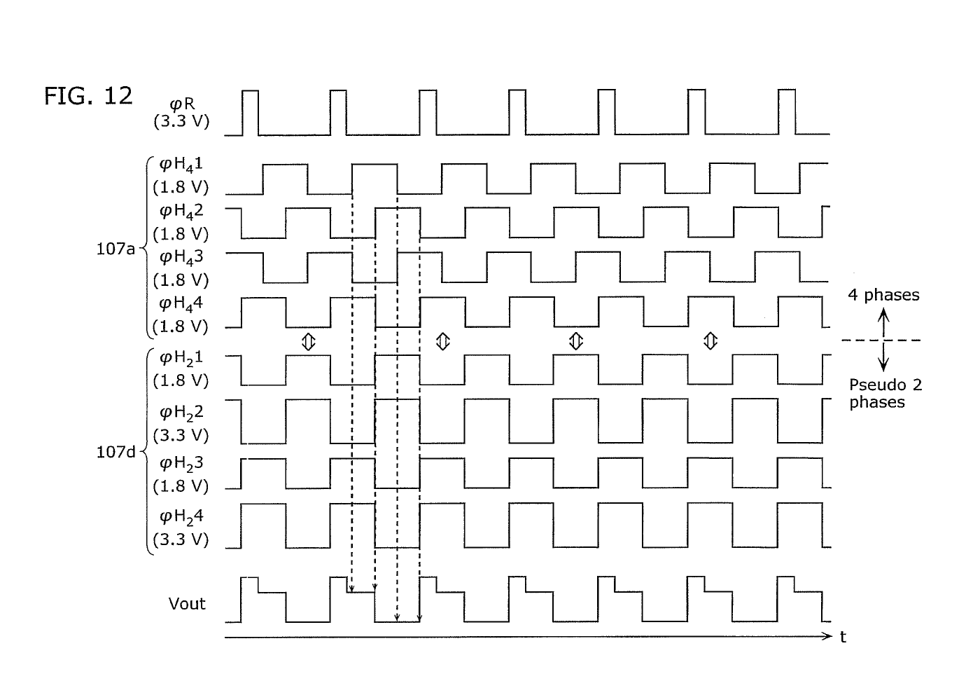

FIG. 12 is a timing chart illustrating behavior of a reset signal φR, 4-phase drive signals, pseudo 2-phase drive signals, and an output signal Vₒᵤₜ in a solid-state imaging device according to the first variation of the second embodiment of the present invention. The behavior timing chart shown in FIG. 12 is different from the behavior timing chart of the solid-state imaging device 400 according to the second embodiment shown in FIG. 11 only in the driving phases of the drive signals φH₄1 to φH₄4 for 4-phase driving the front-stage horizontal CCD unit 107a. The following describes only different points from the second embodiment by omitting explanations for the same points. The voltage amplitudes of the respective phases of the 4-phase drive signals φH₄1 to φH₄4 are all 1.8 V. Furthermore, the 4-phase drive signals are driven at a 50% duty cycle, and each phase is delayed by 90 degrees with respect to a corresponding phase of the drive signal in the previous stage. The timing of the drive signal φH₂1 which is applied to the transfer electrode located in the first stage of the rear-stage horizontal CCD unit 107d and the timing of the drive signal φH₄4 which is applied to the transfer electrode located in the last stage of the front-stage horizontal CCD unit 107a are adjusted so that these drive signals are out of phase by 180 degrees.

By so doing, the noise which is generated in the front-stage horizontal CCD unit 107a and the rear-stage horizontal CCD unit 107b is cancelled so that the coupling noise which is generated between the front-stage horizontal CCD unit 107a and the rear-stage horizontal CCD unit 107b can be reduced.

In the second embodiment of the present invention, an impurity implant region N⁻ where acceptor impurities are implanted may be formed in a part of the input-side region of each of the transfer channel regions of the front-stage horizontal CCD unit 107a, like the horizontal CCD unit of the solid-state imaging device according to the second variation of the first embodiment shown in FIG. 5.

Since this structure allows each of the transfer channel regions of the front-stage horizontal CCD unit to have more potential levels, it is possible to form an incline of potential for facilitating the transfer of signal charges from the input side to the output side within the transfer channel region. Thus, it becomes possible to accelerate the horizontal transfer of signal charges.

### Third Embodiment

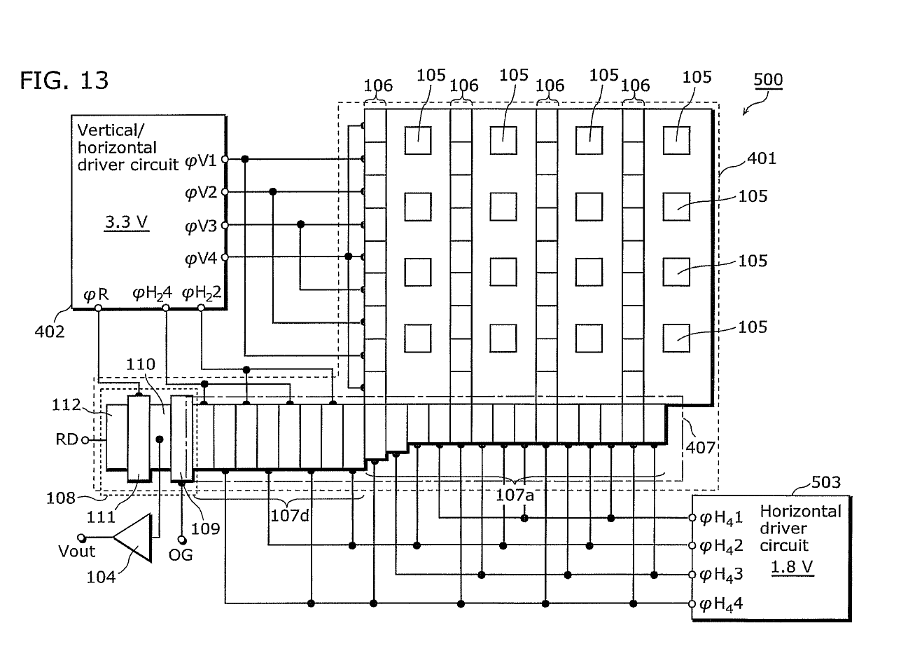

FIG. 13 illustrates a schematic diagram of a solid-state imaging device according to the third embodiment of the present invention. As shown in FIG. 13, a solid-state imaging device 500 includes a solid-state imaging element 401, the vertical/horizontal driver circuit 402, a horizontal driver circuit 503, and the output amplifier 104. The solid-state imaging device 500 shown in FIG. 13 is different from the solid-state imaging device 400 according to the second embodiment shown in FIG. 9 in structures and operations of the horizontal driver circuit 503. The following describes only different points from the second embodiment by omitting explanations for the same points.

The horizontal driver circuit 503 serves as the first driver unit which generates 4-phase drive signals φH₄1, φH₄2, φH₄3, and φH₄4 for driving the front-stage horizontal CCD unit 107a of the horizontal CCD unit 407. Moreover, the horizontal driver circuit 503 serves also as the second driver unit which generates pseudo 2-phase drive signals φH₄2 and φH₄4 for driving a part of the rear-stage horizontal CCD unit 107d of the horizontal CCD unit 407. That is, in the horizontal driver circuit 503, the drive signals φH₄2 and φH₄4 are included in the 4-phase drive signals for driving the front-stage horizontal CCD unit 107a and also serve as part of the pseudo 2-phase drive signals for driving the rear-stage horizontal CCD unit 107d. To the horizontal driver circuit 503, a power supply provides a voltage of 1.8 V, for example. Thus, the horizontal driver circuit 503 generates the drive signals having a voltage level less than the drive signals which are generated by the vertical/horizontal driver circuit 402.

It is to be noted that a voltage of the power which is supplied to the vertical/horizontal driver circuit 402 and the horizontal driver circuit 503 is not limited to the above-stated voltage. The vertical/horizontal driver circuit 402 is a driver IC which is capable of handling a higher voltage than a voltage which the horizontal driver circuit 503 can handle.

The rear-stage horizontal CCD unit 107d serves as the second horizontal transfer unit and is spaced apart from the above photoelectric conversion element unit and the vertical CCD units 106 and disposed between the front-stage horizontal CCD unit 107a and the output unit 108. The 4-phase drive signals φH₄2, φH₂2, φH₄4, and φH₂4 are applied to the four respective adjacent transfer electrodes in the rear-stage horizontal CCD unit 107d. It is to be noted that the drive signals φH₄2 and φH₂2 are in phase and have different voltage amplitudes of 1.8 V and 3.3 V, respectively. Likewise, the drive signals φH₄4 and φH₂4 are in phase and have different voltage amplitudes of 1.8 V and 3.3 V, respectively. That is, the drive signals for driving two adjacent transfer electrodes in the rear-stage horizontal CCD unit 107d have different voltage amplitudes.

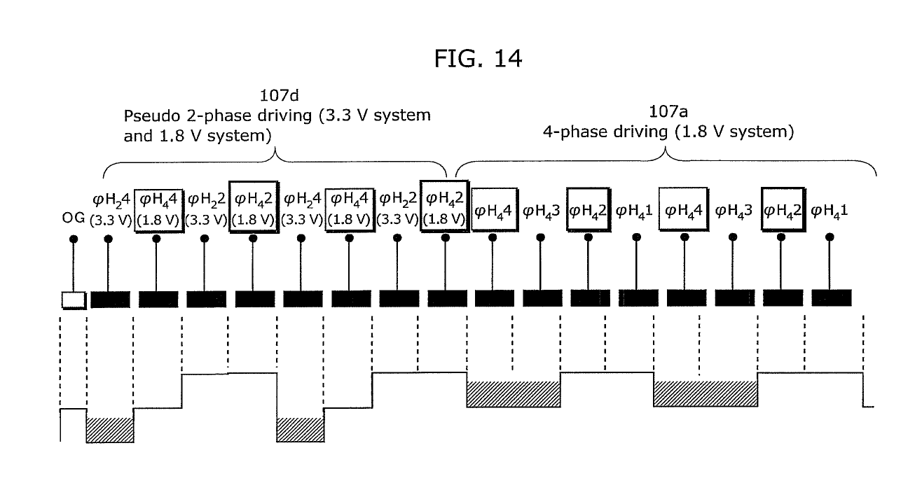

FIG. 14 illustrates a cross-sectional diagram and potential distribution of the horizontal CCD unit of the solid-state imaging device according to the third embodiment of the present invention. As shown in FIG. 14, the 4-phase drive signals φH₄1 to φH₄4 are applied to the four respective adjacent transfer electrodes in the front-stage horizontal CCD unit 107a. The signal charges which are horizontally transferred are accumulated in the potential well formed across the two adjacent transfer electrodes. This allows a smooth horizontal transfer in the front-stage horizontal CCD unit 107a even when the 4-phase drive signals φH₄1 to φH₄4 are set at “H” level (1.8 V) which is lower than “H” level (3.3 V) of the pseudo 2-phase drive signals φH₂2 and φH₂4 in the rear-stage horizontal CCD unit 107d.

Furthermore, in the rear-stage horizontal CCD unit 107d, the drive signals for driving the two adjacent transfer electrodes have different voltage amplitudes (1.8 V and 3.3 V) as described above.

With the above structure, it becomes possible to form the incline of potential for transferring signal charges between adjacent transfer channel regions, without implanting acceptor impurities in the transfer channel regions of the rear-stage horizontal transfer unit 107d. Thus, the step of implanting impurities is omitted, which allows for simplification of the manufacturing process. In addition, the power consumption can be reduced because the voltage applied to the transfer channel region in which no acceptor impurities are implanted is lower than the voltage applied to the transfer channel region in which the acceptor impurities are to be implanted.

In the present embodiment, part of the pseudo 2-phase drive signals for driving the rear-stage horizontal CCD unit 107d is part of the 4-phase drive signals for driving the front-stage horizontal CCD unit 107a, and these signals are pulse signals which have a voltage amplitude of 1.8 V.

This structure allows the voltage supply for providing lower voltage to be used as a part of the voltage supply for the drive signals for driving the rear-stage horizontal CCD unit 107d, as in the case of the solid-state imaging device 400 according to the second embodiment. Furthermore, the solid-state imaging device 500 according to the present embodiment is capable of using the drive signals per se for driving the front-stage horizontal CCD unit 107a as a part of the voltage supply for the drive signals for driving the rear-stage horizontal CCD unit 107d. Thus, it becomes possible to reduce the number of pins in the whole IC.

Next, a horizontal transfer operation in the solid-state imaging device 500 is described. FIG. 15 is a timing chart illustrating behavior of a reset signal φR, 4-phase drive signals, pseudo 2-phase drive signals, and an output signal Vₒᵤₜ in the solid-state imaging device according to the third embodiment of the present invention. The behavior timing chart of the solid-state imaging device 500 shown in FIG. 15 is different from the behavior timing chart of the solid-state imaging device 400 shown in FIG. 11 in that the 4-phase drive signal φH₄2 is used also as the pseudo 2-phase drive signal φH₂1 and that the 4-phase drive signal φH₄4 is used also as the pseudo 2-phase drive signal φH₂3. The following describes only different points from the second embodiment shown in FIG. 11, by omitting explanations for the same points.

The timing of the drive signal φH₄2 which is applied to the transfer electrode located in the first stage of the rear-stage horizontal CCD unit 107d and the timing of the drive signal φH₄4 which is applied to the transfer electrode located in the last stage of the front-stage horizontal CCD unit 107a are adjusted so that these drive signals are out of phase by 180 degrees.

The above structure and operation secure a capacity to accumulate signal charges even when the voltage amplitude of signals for 4-phase driving the front-stage horizontal CCD unit 107a is set to be smaller than the voltage amplitude of signals for driving the vertical CCD units 106 and the rear-stage horizontal CCD unit 107b.

In addition, since the 4-phase drive signals of the front-stage horizontal CCD unit 107a and the pseudo 2-phase drive signals of the rear-stage horizontal CCD unit 107d have a duty ratio of 50%, it becomes possible to cancel the noise which is generated by rising and falling of the 4-phase drive signals and the pseudo 2-phase drive signals.

Furthermore, in the structure according to the present embodiment, the rear-stage horizontal CCD unit 107d that has a small capacitance and is driven by the pseudo 2-phase drive signals with the small number of rising and falling edges is disposed between the output unit 108 and the front-stage horizontal CCD unit 107a that is driven by the 4-phase drive signals with the large number of rising and falling edges. This makes it possible to prevent the generation of the coupling noise in the output voltage, which results from coupling, in the output unit 108, of noise generated in the front-stage horizontal CCD unit 107a.

Thus, the voltage of the horizontal transfer drive signals is decreased, and the coupling noise which is attributed to rising and falling timing of pulses of the drive signals is reduced, which make it possible to generate accurate image signals and reduce the power consumption.

In addition, it becomes possible to use part of the drive signals having lower voltage for driving the front-stage horizontal CCD unit 107a as part of the drive signals for driving the rear-stage horizontal CCD unit 107d. It therefore becomes possible to further reduce the power consumption.

In the third embodiment of the present invention, an impurity implant region N where acceptor impurities are implanted may be formed in a part of the input-side region of each of the transfer channel regions of the front-stage horizontal CCD unit 107a, like the horizontal CCD unit of the solid-state imaging device according to the second variation of the first embodiment shown in FIG. 5.

Since this structure allows each of the transfer channel regions of the front-stage horizontal CCD unit to have more potential levels, it is possible to form an incline of potential for facilitating the transfer of signal charges from the input side to the output side within the transfer channel region. Thus, it becomes possible to accelerate the horizontal transfer of signal charges.

While the above description is based on the embodiments, the solid-state imaging device according to an implementation of the present invention is not limited to the above embodiments. The present invention encompasses other embodiments achieved by combining given constituents in the first to third embodiments and variations thereof, variations obtained by making, to the first to third embodiments and variations thereof, various modifications that those skilled in the art could think of within the spirit and scope of the present invention, and various devices which incorporate the solid-state imaging device according to an implementation of the present invention.

For example, in the second and third embodiments, the shape of each of the transfer channel regions included in the front-stage horizontal CCD unit and the rear-stage horizontal CCD unit may be changed, like the solid-state imaging device according to the third and fourth variations of the first embodiment.

Furthermore, in the second and third embodiments, it may be possible that, of the transfer electrodes included in the front-stage horizontal CCD unit, the transfer electrodes to which the drive signals which are opposite in phase are applied have the same shape, or that the signal lines for the drive signals which are opposite in phase are disposed close to each other, like the solid-state imaging device according to the fifth variation of the first embodiment.

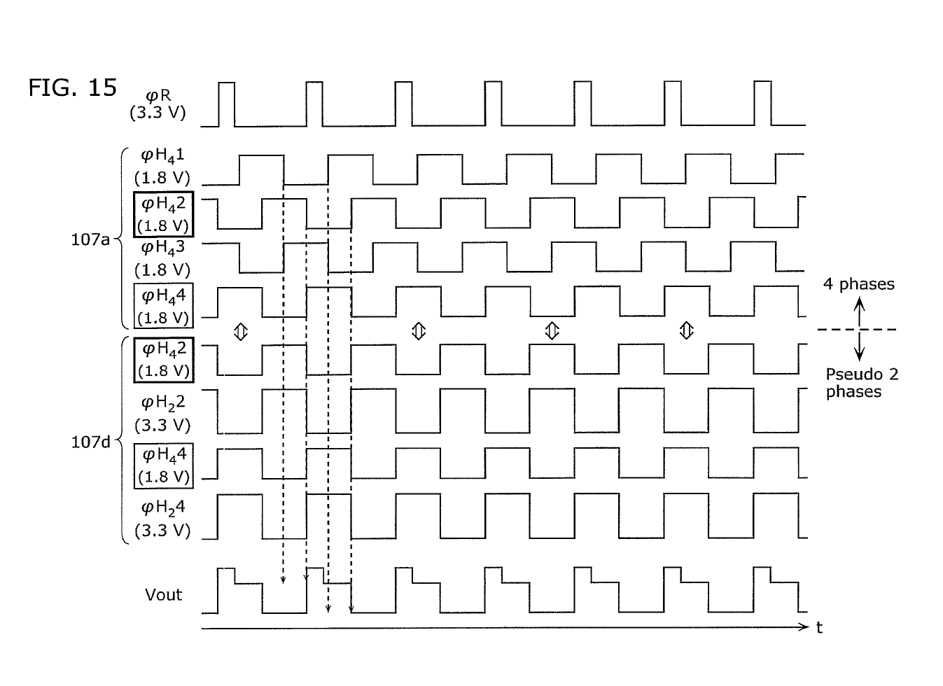

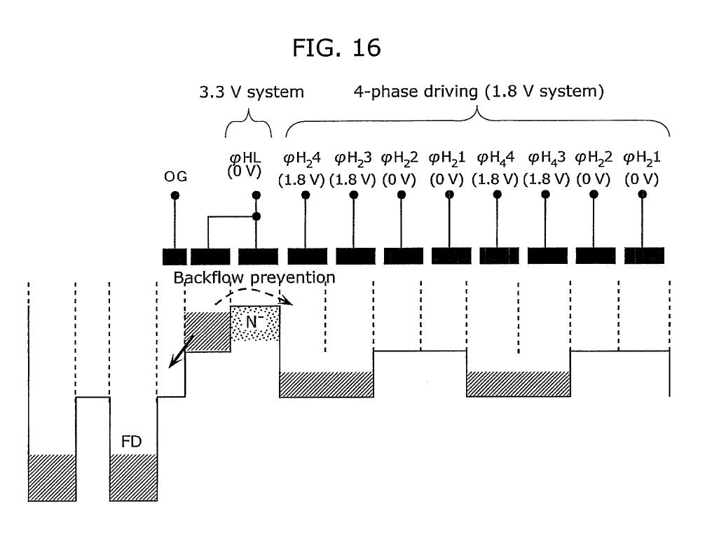

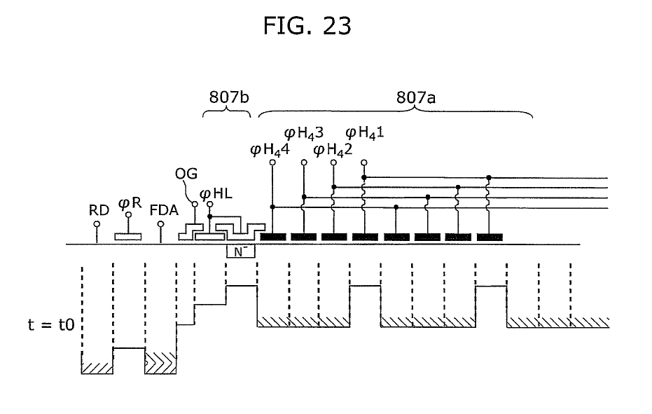

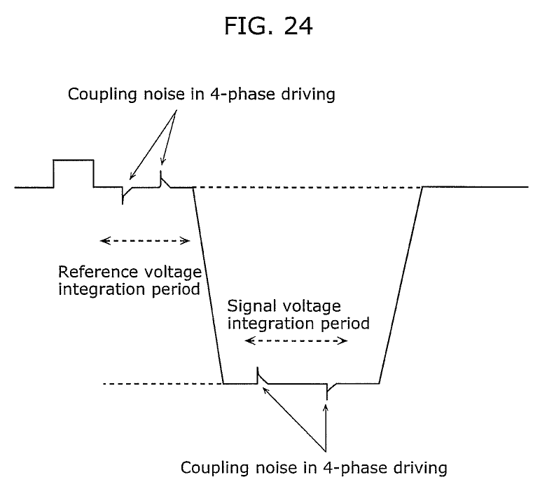

Furthermore, the solid-state imaging device according to an implementation of the present invention may be configured to include, instead of the rear-stage horizontal CCD unit, a terminal electrode unit having two transfer electrodes. FIG. 16 illustrates a cross-sectional diagram and potential distribution of a horizontal CCD unit and a terminal electrode unit of a solid-state imaging device according to an implementation of the present invention. Specifically, a schematic diagram of this solid-state imaging device includes the above terminal electrode unit instead of the rear-stage horizontal CCD unit 107b in the solid-state imaging device 100 according to the first embodiment shown in FIG. 1. The vertical/horizontal driver circuit 102 generates a terminal electrode drive signal φHL instead of the drive signals φH₂1 and φH₂2. This drive signal φHL is applied to the corresponding two transfer electrodes. Furthermore, an impurity implant region N⁻ where acceptor impurities are implanted is formed below the input-side transfer electrode of the two transfer electrodes of the terminal electrode unit. It is to be noted that the present invention includes also the structure in which one transfer electrode is disposed in the terminal electrode unit and N⁻ is present in a part of the area right below the one transfer electrode. In the conventional solid-state imaging device 800 shown in FIG. 23, the 4-phase drive signals for driving the front-stage horizontal CCD unit 807a are driven with a duty ratio of, for example, 5:3. In contrast, in the solid-state imaging device according to the above implementation of the present invention, the 4-phase drive signals for driving the front-stage horizontal CCD unit 107a and the drive signals for driving the terminal electrode unit are driven at a 50% duty cycle, as in the case of the solid-state imaging device 100 shown in FIG. 1, and the voltage amplitude of the 4-phase drive signals is smaller than the voltage amplitude of the drive signals for driving the terminal electrode unit.

The increase in the number of phases for driving the front-stage horizontal CCD unit 107a is accompanied by an increase in the number of rising and falling edges of pulse waveforms of the drive signals. In the above structure, the horizontal transfer drive signals are driven at a 50% duty cycle, so that the noise which is generated by rising and falling of the drive signals for driving the front-stage horizontal CCD unit 107a can be canceled. Thus, the coupling noise which results from coupling of the above noise in the output unit can be prevented from occurring in the output voltage. Furthermore, since the transfer channel of the terminal electrode unit includes an n-type implant region, the signal charges can be prevented from flowing back to the front-stage horizontal CCD unit 107a and thus horizontally transferred smoothly.

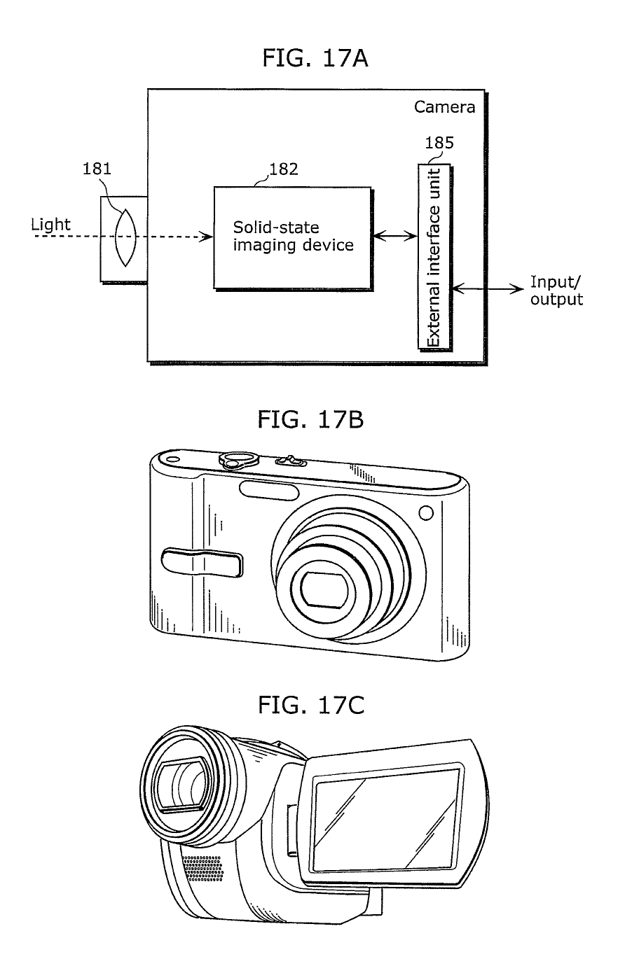

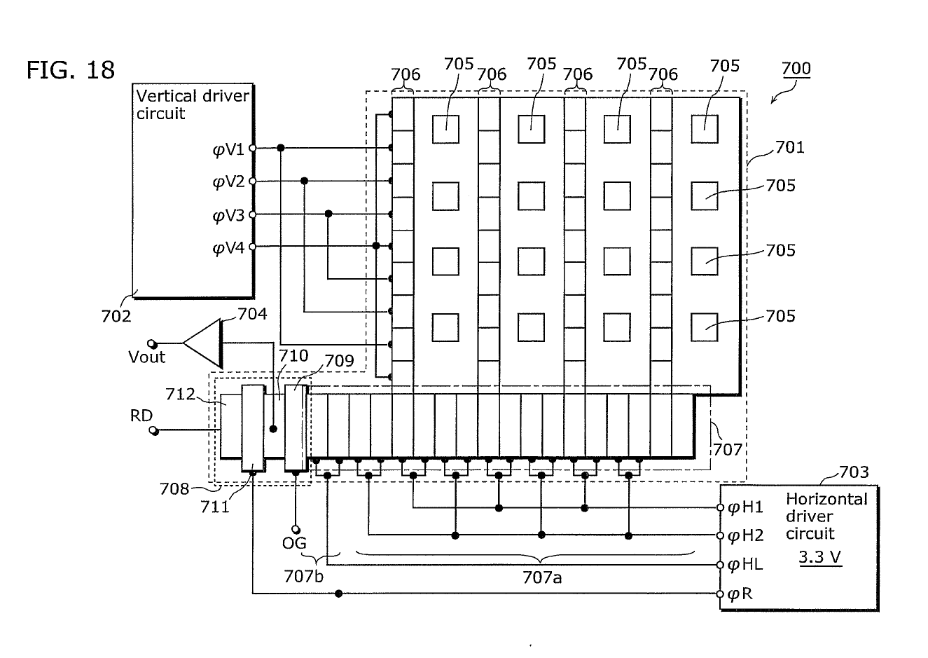

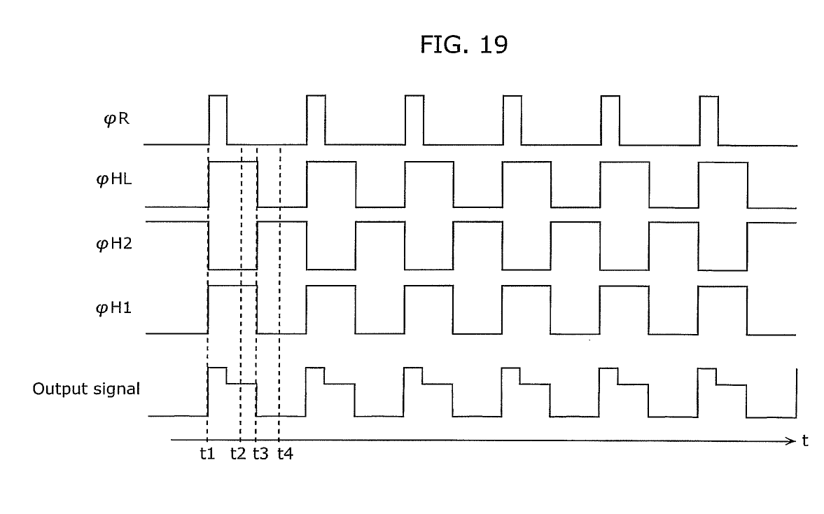

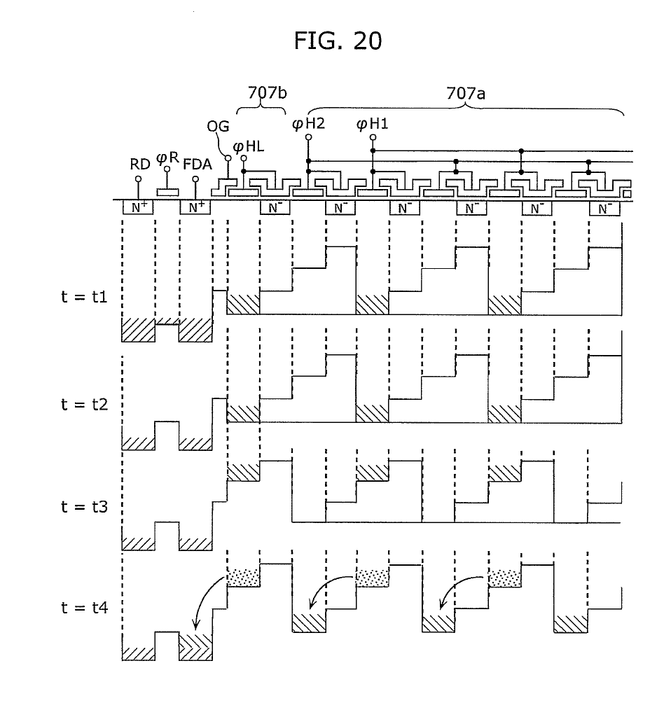

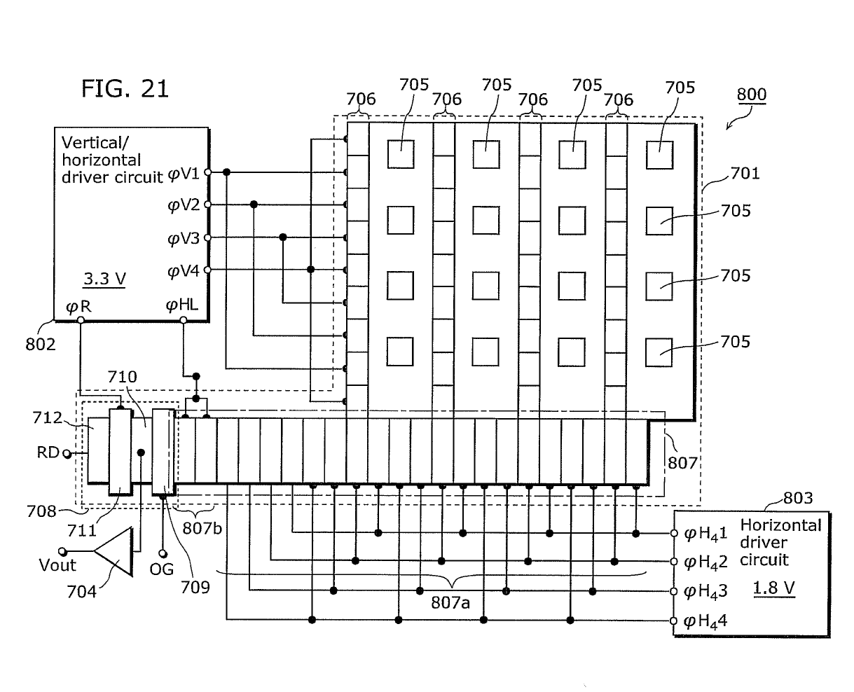

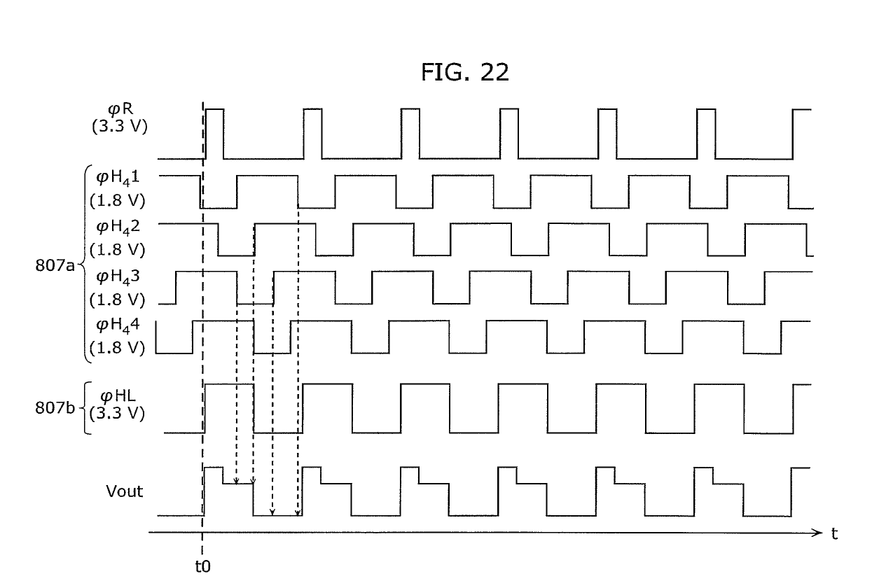

Furthermore, for example, as shown in FIG. 17A, a camera incorporating a solid-state imaging device 182 according to an implementation of the present invention is also encompassed by the present invention. The camera shown in FIG. 17 includes the solid-state imaging device 182 and an external interface unit 185. Light passed through the lens 181 enters the solid-state imaging device 182. Output signals from the solid-state imaging device 182 are provided to outside through the external interface unit 185. Thus, in the solid-state imaging device 182, the voltage of the horizontal transfer drive signals is decreased, and the coupling noise which is attributed to rising and falling timing of pulses of the drive signals is reduced, which make it possible to generate accurate image signals and reduce the power consumption. Such a camera has an advantage of being capable of capturing a clear image even with weak incident light, and is implemented as, for example, a digital still camera shown in FIG. 17B or a video camera shown in FIG. 17C.

While the first to third embodiments describe the cases where the front-stage horizontal CCD unit employs the 4-phase driving system, it is sufficient that the front-state horizontal CCD unit employs an N-phase driving system, where N is an integer equal to or greater than 3. Likewise, while the rear-state horizontal CCD unit employs the 2-phase driving system or the pseudo 2-phase driving system in the above description, it is sufficient that the rear-stage horizontal CCD unit employs an L-phase driving system, where L is an integer which satisfies L N. By thus configuring the rear-state horizontal CCD unit close to the output unit so as to employ the L-phase driving system of which phase is less than the N phases, it is possible to reduce the number of rising and falling edges of driving waveforms and thereby reduce the coupling noise.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The solid-state imaging device according to an implementation of the present invention is capable of obtaining image signals with reduced noise and further reducing the power consumption, and is thus useful for cameras and the like.

What is claimed is:

1. A solid-state imaging device including a charge detecting unit of a floating diffusion amplifier type, said solid-state imaging device comprising:
a plurality of photoelectric conversion elements which convert received light into signal charges;
a plurality of vertical transfer units configured to vertically transfer the signal charges converted by said photoelectric conversion elements;
a first horizontal transfer unit configured to horizontally transfer, according to N-phase drive signals, where N is an integer equal to or greater than 3, the signal charges vertically transferred from said vertical transfer units;
a second horizontal transfer unit spaced apart from said photoelectric conversion elements and said vertical transfer units and disposed between said first horizontal transfer unit and the charge detecting unit, and configured to horizontally transfer the signal charges which have been horizontally transferred from said first horizontal transfer unit, to the charge detecting unit according to L-phase drive signals, where L is an integer equal to or greater than 2 and satisfies L≦N;
a first driver unit configured to generate the N-phase drive signals for driving said first horizontal transfer unit; and
a second driver unit configured to generate the L-phase drive signals for driving said second horizontal transfer unit,
wherein the L-phase drive signals include a signal having a larger voltage amplitude than a voltage amplitude of each of the N-phase drive signals.

2. The solid-state imaging device according to claim 1,
wherein the voltage amplitudes in respective phases of the L-phase drive signals are all V_{L}, and
the voltage amplitudes in respective phases of the N-phase drive signals are all V_{N},
where V_{L} is greater than V_{N}.

3. The solid-state imaging device according to claim 1,
wherein said first horizontal transfer unit includes a plurality of first horizontal transfer electrodes to which the N-phase drive signals are applied, and a first horizontal transfer channel formed below said first horizontal transfer electrodes,
in a part of said first horizontal transfer channel, a first n-type implant region which creates a potential step inside said first horizontal transfer channel is formed for each of said first horizontal transfer electrodes,
said second horizontal transfer unit includes a plurality of second horizontal transfer electrodes to which the L-phase drive signals are applied, and a second horizontal transfer channel formed below said second horizontal transfer electrodes,
in a part of said second horizontal transfer channel, a second n-type implant region which creates a potential step inside said second horizontal transfer channel is formed for each of said second horizontal transfer electrodes, and
the first n-type implant region has a different impurity concentration from an impurity concentration of the second n-type implant region.

4. The solid-state imaging device according to claim 1,
said second horizontal transfer unit includes a plurality of second horizontal transfer electrodes to which the L-phase drive signals are applied, and a second horizontal transfer channel formed below said second horizontal transfer electrodes,
the integer L is a multiple of 2, and
the voltage amplitudes of the L-phase drive signals for driving two adjacent ones of said second horizontal transfer electrodes are different from each other.

5. The solid-state imaging device according to claim 4, further comprising
a third driver unit configured to generate a reset signal for resetting the signal charges accumulated in the charge detecting unit,
wherein, among the voltage amplitudes of the L-phase drive signals, one is the same as a voltage amplitude of the reset signal and an other is the same as the voltage amplitude of one of the N-phase drive signals.

6. The solid-state imaging device according to claim 4,
wherein the voltage amplitude in each phase of the N-phase drive signals is V_{N}, and
the voltage amplitude in each phase of the L-phase drive signals is V_{L} or V_{N},
where V_{L} is greater than V_{N}.

7. The solid-state imaging device according to claim 4,
wherein a part of the N-phase drive signals is common with a part of the L-phase drive signals.

8. The solid-state imaging device according to claim 4,
wherein an n-type implant region which creates a potential step inside said second horizontal transfer channel is not formed in each of said second horizontal transfer electrodes.

9. The solid-state imaging device according to claim 1,
wherein said first driver unit and said second driver unit respectively generate the N-phase drive signals having a 50% duty cycle and the L-phase drive signals having a 50% duty cycle.

10. The solid-state imaging device according to claim 9,
wherein rising timing and falling timing in a phase of the N-phase drive signals are the same, respectively, as falling timing and rising timing in an other phase of the N-phase drive signals.

11. The solid-state imaging device according to claim 9,
wherein said first horizontal transfer unit includes said first horizontal transfer electrodes to which the N-phase drive signals out of phase by 180 degrees are applied and which are of equal length and width.

12. The solid-state imaging device according to claim 11, comprising
a plurality of lines connected to said first horizontal transfer electrodes and through which the N-phase drive signals are supplied to said first horizontal transfer electrodes,
wherein, among said lines, lines through which signal voltages out of phase by 180 degrees are concurrently supplied are adjacent to each other.

13. The solid-state imaging device according to claim 9,
wherein rising timing and falling timing of one of the N-phase drive signals which is applied to one of horizontal transfer electrodes which is located at a last stage of said first horizontal transfer unit are the same, respectively, as falling timing and rising timing of one of the L-phase drive signals which is applied to one of second horizontal transfer electrodes which is located at a first stage of said second horizontal transfer unit.

14. The solid-state imaging device according to claim 1,
wherein said second horizontal transfer unit includes a plurality of second horizontal transfer electrodes to which the L-phase drive signals are applied, and a second horizontal transfer channel formed below said second horizontal transfer electrodes, and
said second horizontal transfer channel includes a plurality of second horizontal transfer channel regions which correspond to said second horizontal transfer electrodes and whose lengths in a transfer direction or widths in an orthogonal direction to the transfer direction are different from each other.

15. The solid-state imaging device according to claim 1,
wherein said first horizontal transfer unit includes a plurality of first horizontal transfer electrodes to which the N-phase drive signals are applied, and a first horizontal transfer channel formed below said first horizontal transfer electrodes, and
said first horizontal transfer channel includes a plurality of first horizontal transfer channel regions which correspond to said first horizontal transfer electrodes and whose lengths in a transfer direction or widths in an orthogonal direction to the transfer direction are different from each other.

16. A solid-state imaging device including a charge detecting unit of a floating diffusion amplifier type, said solid-state imaging device comprising:
a plurality of photoelectric conversion elements which convert received light into signal charges;
a plurality of vertical transfer units configured to vertically transfer the signal charges converted by said photoelectric conversion elements;
a first horizontal transfer unit configured to horizontally transfer, according to N-phase drive signals, where N is an integer equal to or greater than 3, the signal charges vertically transferred from said vertical transfer units;
a second horizontal transfer unit including a second horizontal transfer electrode for horizontally transferring, to the charge detecting unit, the signal charges horizontally transferred from said first horizontal transfer unit, and a second horizontal transfer channel formed below said second horizontal transfer electrode;
a first driver unit configured to generate the N-phase drive signals for driving said first horizontal transfer unit; and
a second driver unit configured to generate a second horizontal transfer drive signal for driving said second horizontal transfer unit,
wherein a voltage amplitude of each of the N-phase drive signals is smaller than a voltage amplitude of each of the second horizontal transfer drive signals,
the N-phase drive signals have a 50% duty cycle, and the second horizontal transfer drive signals have a 50% duty cycle, and
in a part of said second horizontal transfer channel, a second n-type implant region which creates a potential step inside said second horizontal transfer channel is formed for each of said second horizontal transfer electrodes.

17. A camera comprising said solid-state imaging device according to claim 1.
